(19) United States
(12) Patent Application Publication
(10) Pub. No.: US 2025/0244543 A1
(43) Pub. Date: Jul. 31, 2025

(54) OPTICAL SIGNAL REDIRECTION STRUCTURE FOR PHOTONICS DEVICE

(71) Applicant: Taiwan Semiconductor Manufacturing Company, Ltd., Hsinchu (TW)

(72) Inventors: Ting-Jung CHEN, Hsinchu County (TW); Shih-Wei LIN, Hsinchu City (TW)

(21) Appl. No.: 18/423,888

(22) Filed: Jan. 26, 2024

(51) Int. Cl. G02B 6/42

(52) U.S. Cl. CPC G02B 6/4214

(57) ABSTRACT

Some implementations herein provide an optical signal redirection structure. The optical signal redirection structure includes a planar silicon surface having a <110> crystal grain orientation. The optical signal redirection structure includes a dielectric region over the planar silicon surface. The optical signal redirection structure includes a mirror structure suspended in the dielectric region, where the mirror structure is approximately parallel to the planar silicon surface.

### BACKGROUND

A semiconductor device may be configured to use optical signals for high speed and secure data transmission. An optical signal may be transferred through a waveguide in the semiconductor device. The waveguide enables confinement of the optical signal, which may reduce optical loss and increase propagation efficiency for the optical signal. Data may be encoded into an optical signal by modulating light into optical pulses through an optical modulator. The optical pulses are then transferred to the waveguide for propagation to other regions of the semiconductor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of an example semiconductor photonics device described herein.

FIGS. 3A and 3B are diagrams of example implementations of a mirror structure described herein.

FIGS. 4A-4H are diagrams of an example implementation of forming a portion of a semiconductor photonics device described herein.

FIGS. 5A-5E are diagrams of an example implementation of forming an optical signal redirection structure within a semiconductor photonics device described herein.

FIGS. 6A-6C are diagrams of an example implementation of forming a portion of a semiconductor photonics device described herein.

FIGS. 7A-7C are diagrams of an example implementation of a masking structure described herein.

FIGS. 8A-8C are diagrams of example implementations related to formation of an optical signal redirection structure described herein.

FIG. 9 is a flowchart of an example process associated with forming an optical signal redirection structure described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An optical modulator of a photonic integrated circuit may be configured to receive an input optical signal and an input electrical signal, and may be configured to encode data from the input electrical signal onto the input optical signal by modulating the input optical signal to generate a modulated optical signal. A waveguide of the photonic integrated circuit may be configured to receive the modulated optical signal and provide the modulated optical signal to an output optical fiber on which the modulated optical signal is transmitted to another device. In this way, the photonic integrated circuit may facilitate high-speed and/or high-bandwidth optical communications for applications such as telecommunications, data center, and/or high-performance compute (HPC), among other examples.

In some cases, a semiconductor photonics device includes the photonic integrated circuit and is coupled with an output optical fiber at a top surface of the semiconductor photonics device. To facilitate coupling of a modulated optical signal to the output optical fiber at the top surface of the semiconductor photonics device, the semiconductor photonics device may include an optical signal redirection structure. The optical signal redirection structure may include a mirror structure that is above and parallel to a planar silicon surface, where the planar silicon surface is formed at an angle relative to a top surface of substrate. The mirror structure may redirect the modulated optical signal received from a first direction to a second direction that is toward the output optical fiber. Techniques to fabricate the optical signal redirection structure may include forming the planar silicon surface using a dry etch operation. However, geometric properties of the planar silicon surface formed using the dry etch operation (e.g., a nominal angle and/or a flatness of the planar silicon surface) may be insufficient for accurate formation and/or positioning of the mirror structure above the planar silicon surface. Such inaccurate formation and/or positioning of the mirror structure may cause an optical signal loss during redirection of the modulated optical signal from the first direction to the second direction and decrease a coupling performance between the semiconductor photonics device and the output optical fiber.

In some implementations described herein, a semiconductor photonics device includes a photonic integrated circuit and is coupled with an output optical fiber at a top surface of the semiconductor photonics device. To facilitate coupling of a modulated optical signal to the output optical fiber at the top surface of the semiconductor photonics device, the semiconductor photonics device includes an optical signal redirection structure. The optical signal redirection structure includes a mirror structure that is above and parallel to a planar silicon surface, where the planar silicon surface penetrates into a substrate of the semiconductor photonics device at an angle. The mirror structure redirects the modulated optical signal received from a first direction to a second direction that is toward the output optical fiber. Techniques to fabricate the optical signal redirection structure include forming the planar silicon surface using a wet chemical etch operation. The wet chemical etch operation exposes a <110> crystal grain orientation to improve geometric properties (e.g., the nominal angle and/or the flatness) relative to another planar silicon surface formed using the dry etch operation.

In this way, optical signal losses during redirection of the modulated optical signal from the first direction to the second direction are decreased to improve a coupling performance between the semiconductor photonics device and the output optical fiber. The improved coupling performance increases an operating efficiency of the semiconductor photonics device, among other examples.

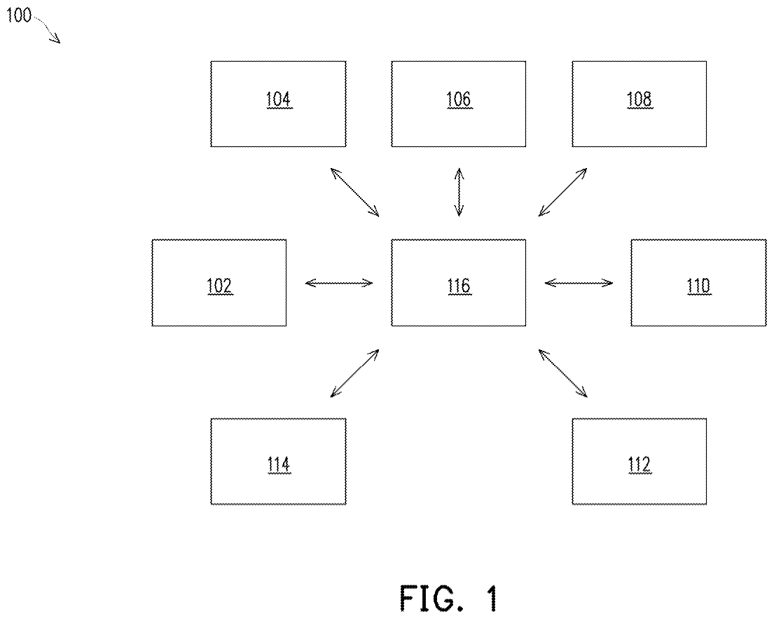

FIG. 1 is a diagram of an example environment 100 in which systems and/or methods described herein may be implemented. As shown in FIG. 1, the example environment 100 may include a plurality of semiconductor processing tools 102-114 and a wafer/die transport tool 116. The plurality of semiconductor processing tools 102-114 may include a deposition tool 102, an exposure tool 104, a developer tool 106, an etch tool 108, a planarization tool 110, a plating tool 112, an ion implantation tool 114, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma enhanced CVD (PECVD) tool, a low-pressure CVD (LPCVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the example environment 100 includes a plurality of different types of deposition tools 102. “Deposition tool 102,” as used herein, may refer to one or more deposition tools 102, one or more of the same type of deposition tools 102, and/or one or more different types of deposition tools 102, among other examples.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet chemical etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The ion implantation tool 114 is a semiconductor processing tool that is capable of implanting ions into a substrate. The ion implantation tool 114 may generate ions in an arc chamber from a source material such as a gas or a solid. The source material may be provided into the arc chamber, and an arc voltage is discharged between a cathode and an electrode to produce a plasma containing ions of the source material. One or more extraction electrodes may be used to extract the ions from the plasma in the arc chamber and accelerate the ions to form an ion beam. The ion beam may be directed toward the substrate such that the ions are implanted below the surface of the substrate.

The wafer/die transport tool 116 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 116 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations).

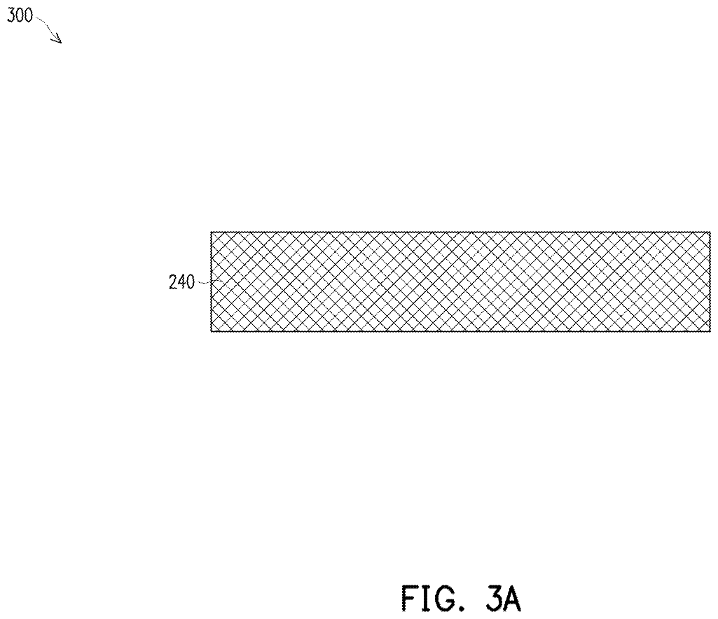

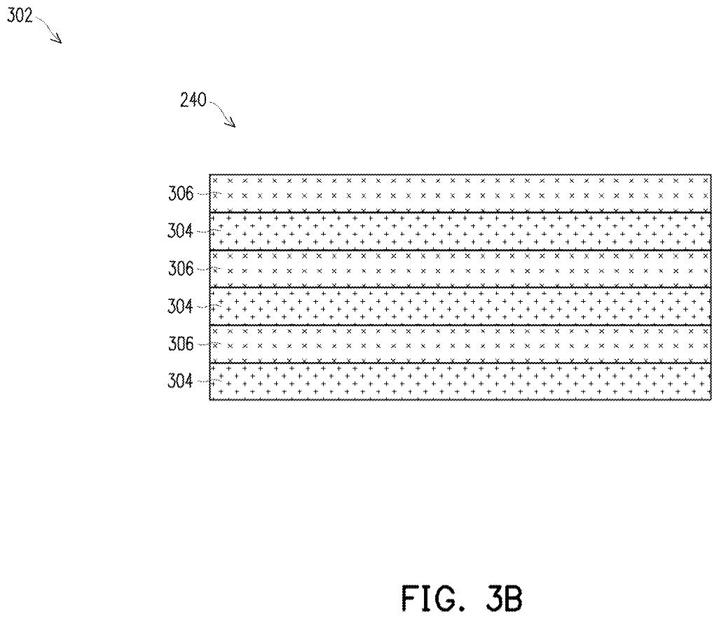

In some implementations, one or more of the semiconductor processing tools 102-114 perform a series of semiconductor processing operations described herein. The series of semiconductor processing operations includes forming a hard mask structure on a silicon substrate. The series of semiconductor processing operations includes removing silicon using the hard mask structure to expose a planar silicon surface having a <110> crystal grain orientation. The series of semiconductor processing operations includes forming, over the planar silicon surface, a portion of a dielectric region that is approximately parallel to the planar silicon surface. The series of semiconductor processing operations includes forming, over the portion of the dielectric region, a mirror structure that is approximately parallel to the planar silicon surface. One or more of the semiconductor processing tools 102-114 may perform other semiconductor processing operations described herein, such as in connection with FIGS. 3A, 3B, 4A-4H, 5A-5E, 6A-6C, 7A-7C, 8A-8C, and/or 10, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

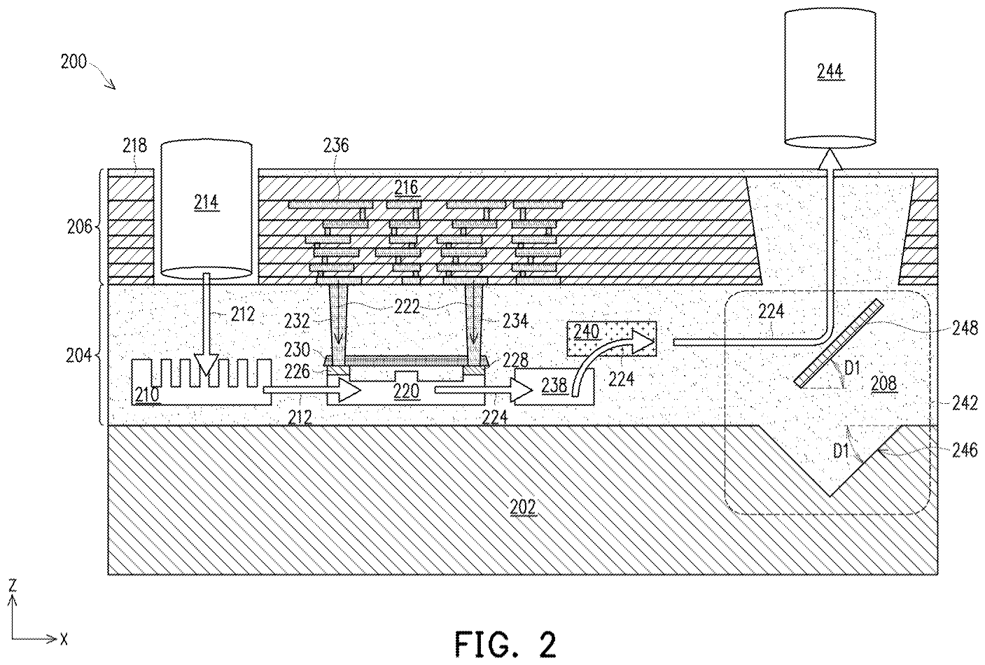

FIG. 2 is a diagram of an example semiconductor photonics device 200 described herein. The semiconductor photonics device 200 may include a photonics integrated circuit (PIC) that is configured to transmit and/or receive modulated optical signals (e.g., an optical signal that is modulated to encode data in the optical signal). In general, the semiconductor photonics device 200 may be configured to convert between electrical signals and optical signals for high-bandwidth optical communications.

FIG. 2 illustrates a cross-sectional view of the semiconductor photonics device 200. As shown in FIG. 2, the semiconductor photonics device 200 may include a silicon substrate 202, a device region 204 above the silicon substrate 202, and a backend region 206 above the device region 204. The silicon substrate 202 may include a silicon (Si) substrate and/or another type of semiconductor substrate. The device region 204 may include a dielectric region 208. The dielectric region 208 may include one or more layers of dielectric material. The dielectric material may include an oxide material such as a silicon oxide (SiOₓ). Alternatively, the dielectric material may include a silicon nitride (SiₓN_{y}), a silicon oxynitride (SiON), tetraethyl orthosilicate oxide, phosphosilicate glass (PSG), borophosphosilicate glass (BPSG), fluorinated silicate glass (FSG), carbon doped silicon oxide, and/or another dielectric material.

The device region 204 may further include a grating coupler 210 in the dielectric region 208. The grating coupler 210 may include a semiconductor structure (e.g., a silicon (Si) structure and/or other types of semiconductor structure) that are configured to receive an input optical signal 212 from an input optical fiber 214 that extends through one or more dielectric layers 216 in the backend region 206 of the semiconductor photonics device 200. The grating coupler 210 may direct the input optical signal 212 toward an optical modulator 220 included in the dielectric region 208 of the device region 204. The grating coupler 210 may be configured to diffract the input optical signal 212 from an off-plane direction (e.g., a z-direction) in the semiconductor photonics device 200 to an in-plane direction (e.g., an x-direction) that is in the plane of the optical modulator 220. The grating coupler 210 may include a plurality of periodic gratings. The periodicity of the periodic gratings may be selected to achieve diffraction of one or more wavelengths of the input optical signal 212. In some implementations, the periodicity of the periodic gratings may be selected based on the wavelength of the input optical signal 212.

The one or more dielectric layers 216 of the backend region 206 may include one or more layers of dielectric material. The dielectric material may include a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silicate glass (FSG), carbon doped silicon oxide, and/or another dielectric material. A passivation layer 218 may be included over and/or on the one or more dielectric layers 216, and the passivation layer 218 may include one or more dielectric materials, one or more polymer materials, and/or one or more materials of another type.

The optical modulator 220 may include a micro-ring modulator (MRM), a Mach Zender modulator (MZM), and/or another type of optical modulator that is configured to modulate the input optical signal 212, based on an input electrical signal 222, to generate a modulated optical signal 224. The input electrical signal 222 may be or may correspond to a stream of digital data (e.g., 1-values and 0-values). The optical modulator 220 may modulate the amplitude of the input optical signal 212, the phase of the input optical signal 212, the frequency of the input optical signal 212, and/or another property of the input optical signal 212 based on the stream of digital data of the input electrical signal 222.

The input electrical signal 222 may be provided to contacts 226 and/or 228 of the optical modulator 220. The contacts 226 and/or 228 may include one or more types of doped semiconductor materials. For example, the contact 226 may be a p-doped contact (e.g., may include a semiconductor material that is doped with one or more p-type dopants), and the contact 228 may be an n-doped contact (e.g., may include a semiconductor material that is doped with one or more n-type dopants). Thus, the optical modulator 220 may include a P-N junction. The semiconductor material may include silicon (Si), germanium (Ge), silicon germanium (SiGe), and/or another semiconductor material. The p-type dopant(s) may include p-type ions of a p-type material (e.g., boron (B) or germanium (Ge), among other examples). The n-type dopant(s) may include n-type ions of an n-type material (e.g., phosphorous (P) or arsenic (As), among other examples).

When the input electrical signal 222 is applied to the P-N junction of the optical modulator 220, a junction depletion width of the P-N junction is modified. This results in changes in concentrations of electrons and holes within the optical modulator 220. The changes in concentrations of electrons and holes may lead to changes of the effective refractive index of the optical modulator 220, which may modulate the light intensity of the input optical signal 212 within the optical modulator 220, thereby enabling the input electrical signal 222 to be translated to the modulated optical signal 224.

A capping layer 230 may be included over and/or on the contacts 226 and 228. The capping layer 230 may include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silicate glass (FSG), carbon doped silicon oxide, and/or another dielectric material.

The device region 204 may include a plurality of interconnect structures 232 and 234 that are included in the dielectric region 208 and coupled with the optical modulator 220. For example, the interconnect structure 232 may be electrically coupled and/or physically coupled with the contact 226, and the interconnect structure 234 may be electrically coupled and/or physically coupled with the contact 228. The interconnect structures 232 and 234 may each include one or more electrically conductive materials, such as tungsten (W), cobalt (Co), ruthenium (Ru), titanium (Ti), aluminum (Al), copper (Cu), and/or gold (Au), among other examples of conductive materials. The interconnect structures 232 and 234 may each include vias, trenches, contact plugs, and/or another type of conductive structures.

The interconnect structures 232 and 234 may be electrically coupled and/or physically coupled with one or more metallization layers 236 in the one or more dielectric layers 216 of the backend region 206 of the semiconductor photonics device 200. The input electrical signal 222 may be provided to the optical modulator 220 through the metallization layer(s) 236 and through the interconnect structures 232 and 234. The metallization layer(s) 236 may each include one or more electrically conductive materials, such as tungsten (W), cobalt (Co), ruthenium (Ru), titanium (Ti), aluminum (Al), copper (Cu), and/or gold (Au), among other examples of conductive materials. The metallization layer(s) 236 may each include vias, trenches, contact plugs, conductive pads, conductive pillars, and/or another type of metallization layers.

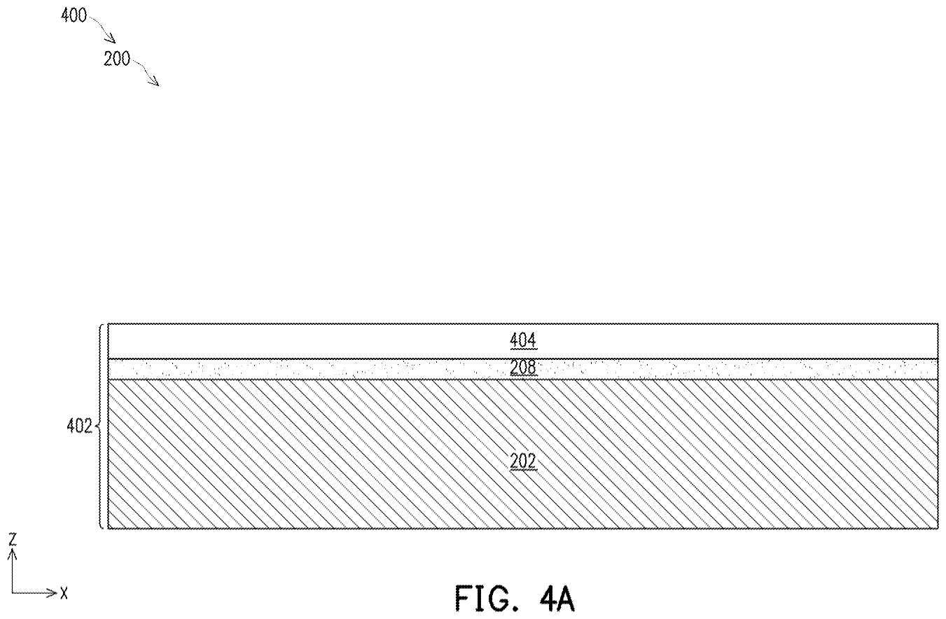

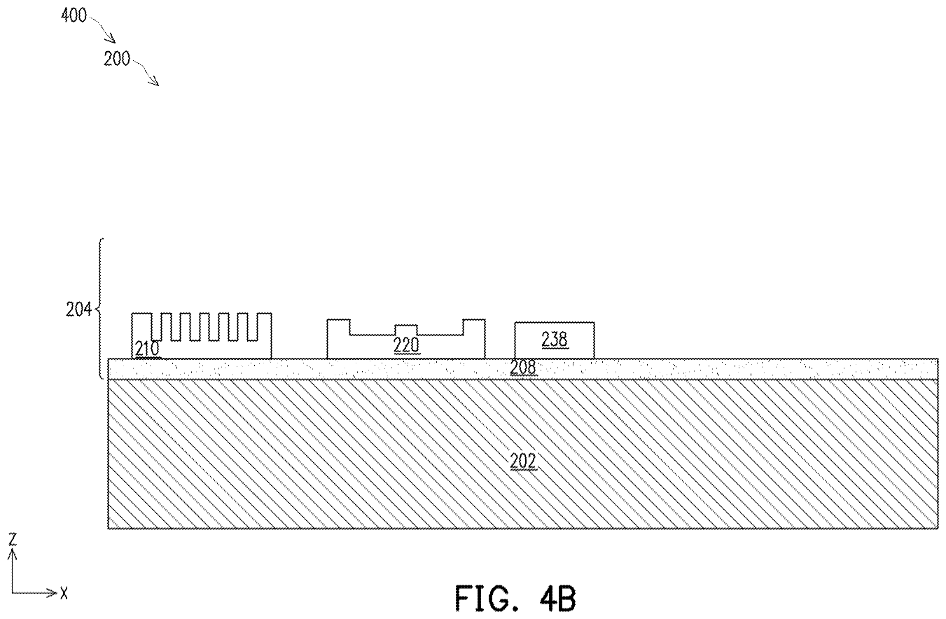

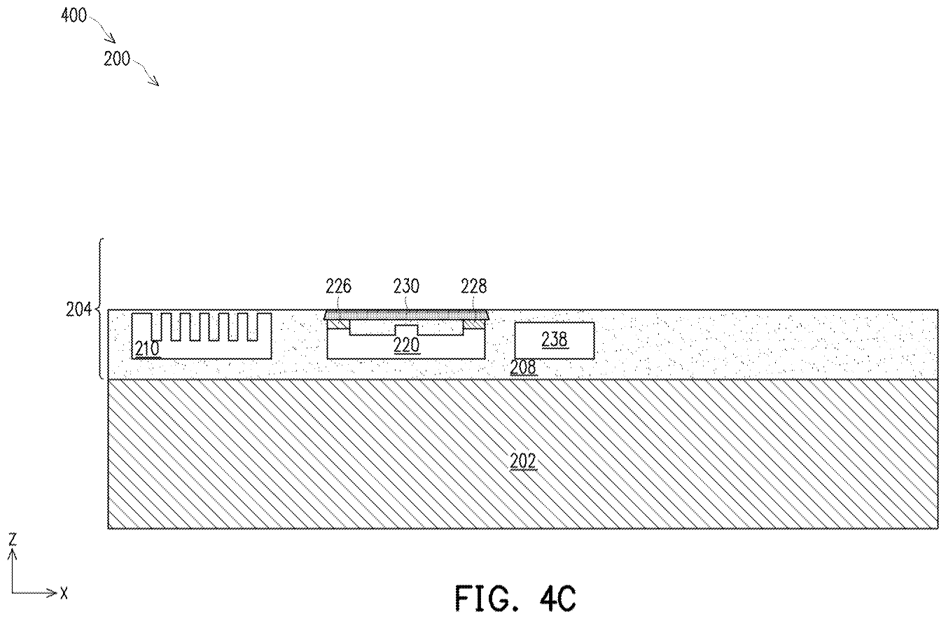

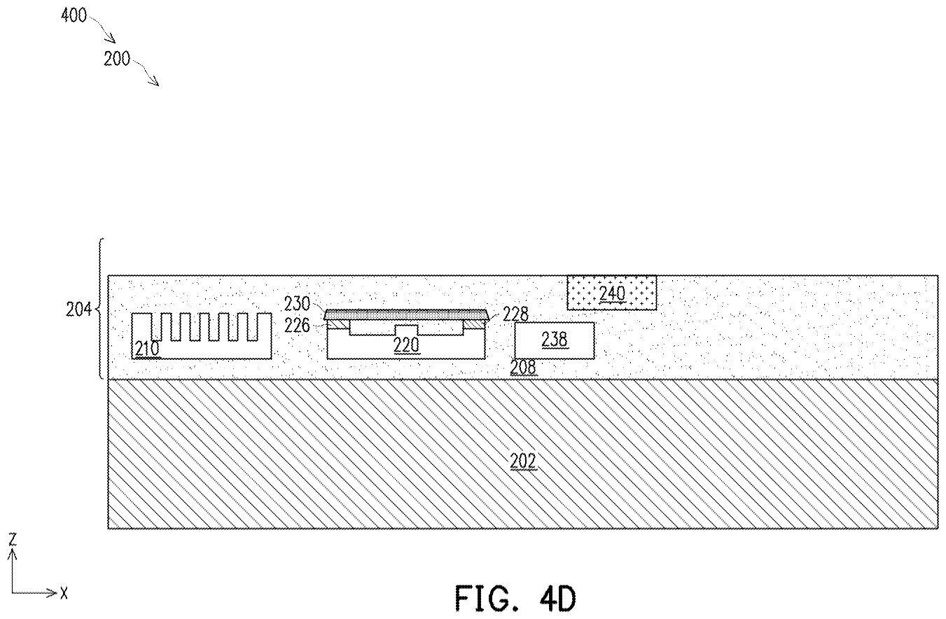

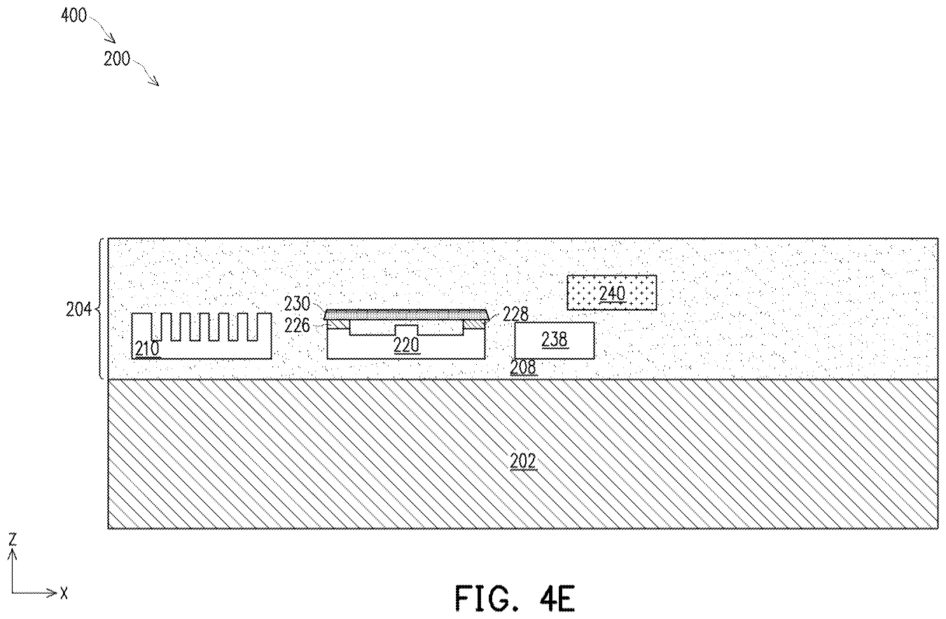

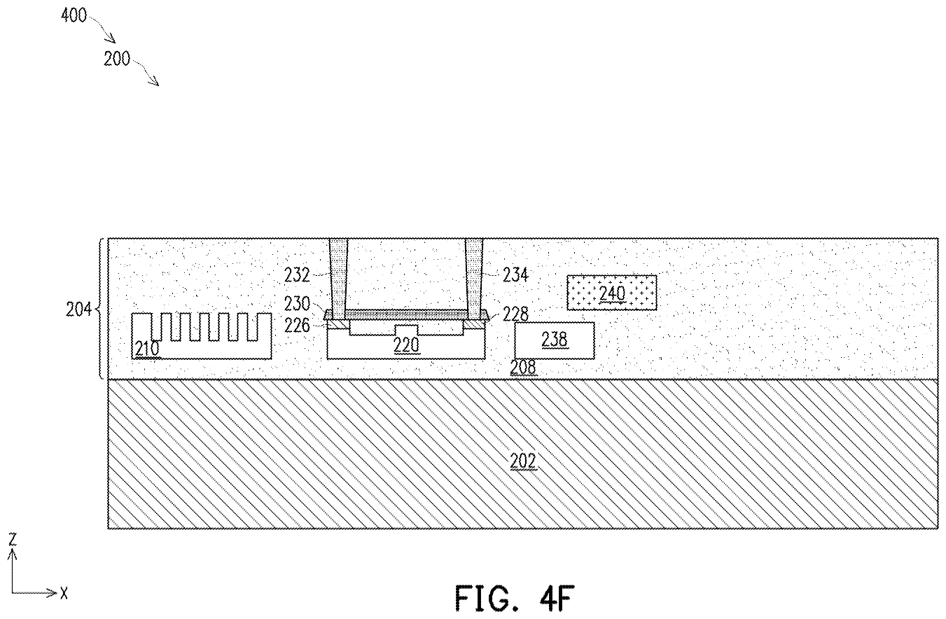

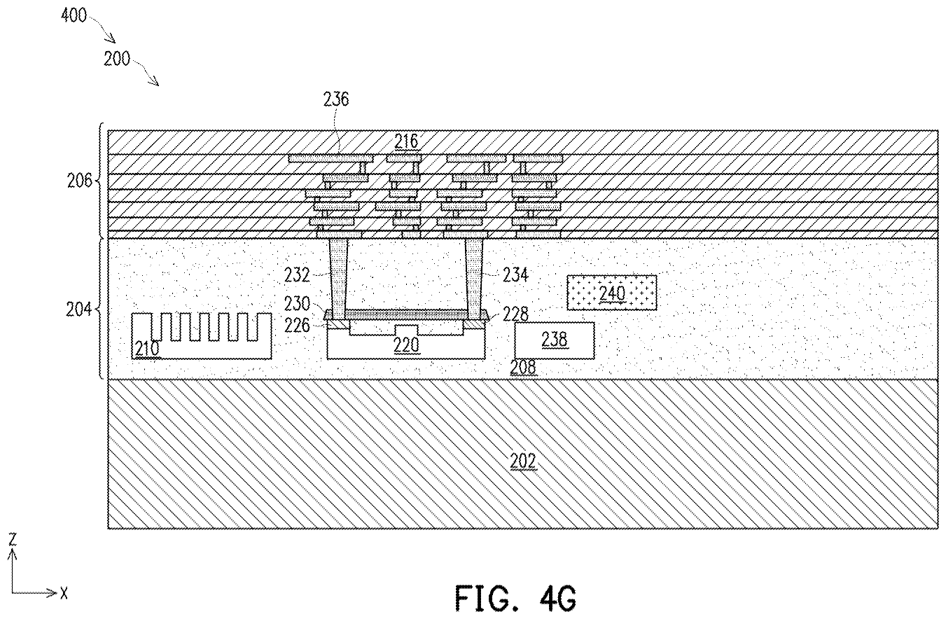

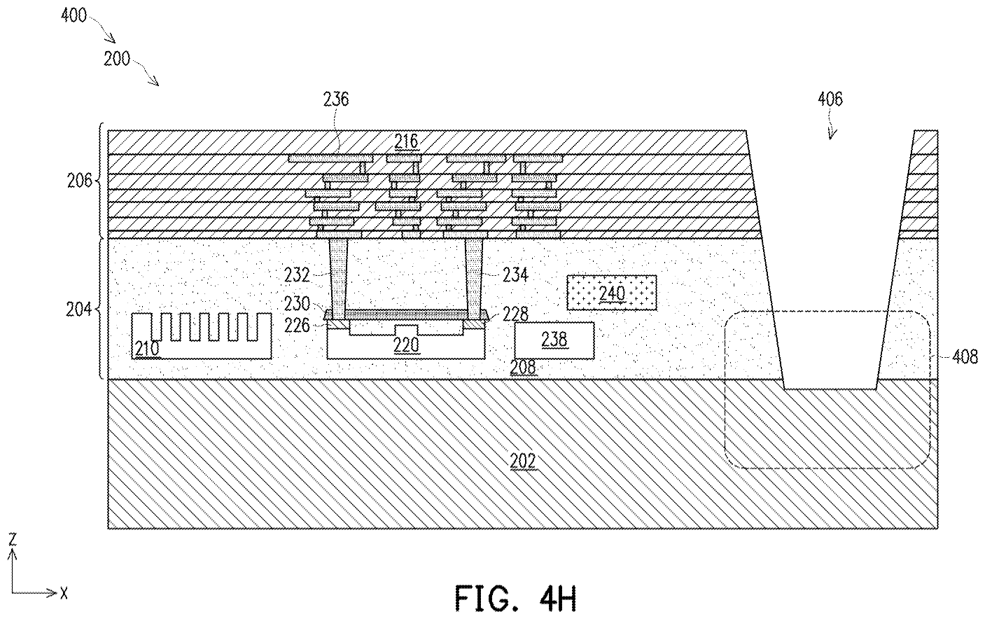

The optical modulator 220 may be configured to provide the modulated optical signal 224 to a semiconductor waveguide 238 included in the dielectric region 208 of the device region 204. The semiconductor waveguide 238 may include a silicon (Si) waveguide and/or another type of semiconductor waveguide. The semiconductor waveguide 238 may be configured to receive the modulated optical signal 224 and to transfer the modulated optical signal 224 to a dielectric waveguide 240 located above the semiconductor waveguide 238 in the dielectric region 208 of the device region 204. The semiconductor waveguide 238 may be manufactured from the same semiconductor layer as the optical modulator 220 and/or as the grating coupler 210, as described in connection with FIGS. 4A-4H.

The dielectric waveguide 240 may include a slab waveguide that includes a plurality of dielectric layers. The dielectric waveguide 240 may include a high dielectric constant (high-k) core layer that is sandwiched between low dielectric constant (low-k) cladding layers. This enables the modulated optical signal 224 to be loosely confined within the high-k core layer and to achieve total internal reflections of the modulated optical signal 224 in the high-k dielectric core layer, which may enable low optical loss and/or increased signal propagation speeds relative to the semiconductor waveguide 238. The low-k dielectric cladding layers may each include a low-k dielectric material, such as a silicon oxide (SiOₓ such as SiO₂), that has a dielectric constant included in a range of approximately 3.9 to approximately 4.2. The high-k dielectric core layer may include a high-k dielectric material that has a dielectric constant greater than 4.2 and included in a range of approximately 7 to approximately 1500. However, other values for the ranges of the dielectric constants of the low-k dielectric cladding layers and the high-k dielectric core layer are within the scope of the present disclosure. Examples of high-k dielectric materials that may be used for the high-k dielectric core layer include a strontium titanate (SrTiOₓ such as SrTiO₃), a barium titanate (BaTiOₓ such as BaTiO₃), a barium strontium Titanate (BaSrTiOₓ such as BaSrTiO₃), a lead zirconate titanate (PbZrTiOₓ such as PbZrTiO₃), a silicon nitride (SiₓN_{y} such as Si₃N₄), a titanium dioxide (TiOₓ such as TiO₂), a zirconium oxide (ZrOₓ such as ZrO₂), an aluminum oxide (AlₓO_{y} such as Al₂O₃), a hafnium oxide (HfOₓ such as HfO₂), a hafnium silicate (HfSiOₓ such as HfSiO₄), a zirconium titanate (ZrTiOₓ such as ZrTiO₄), a tantalum oxide (TaₓO_{y} such as Ta₂O₅), and/or a yttrium oxide (YₓO_{y} such as Y₂O₃), among other examples.

The dielectric waveguide 240 directs the modulated optical signal 224 toward an optical signal redirection structure 242. The optical signal redirection structure 242 includes a planar silicon surface 246 (e.g., an approximately planar silicon surface), where the planar silicon surface 246 penetrates into the silicon substrate 202 at an angle D1 from a top, approximately horizontal surface of the silicon substrate 202.

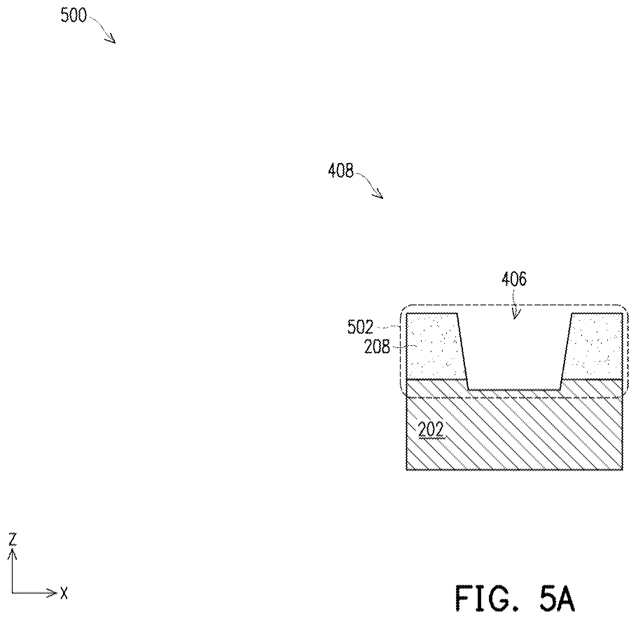

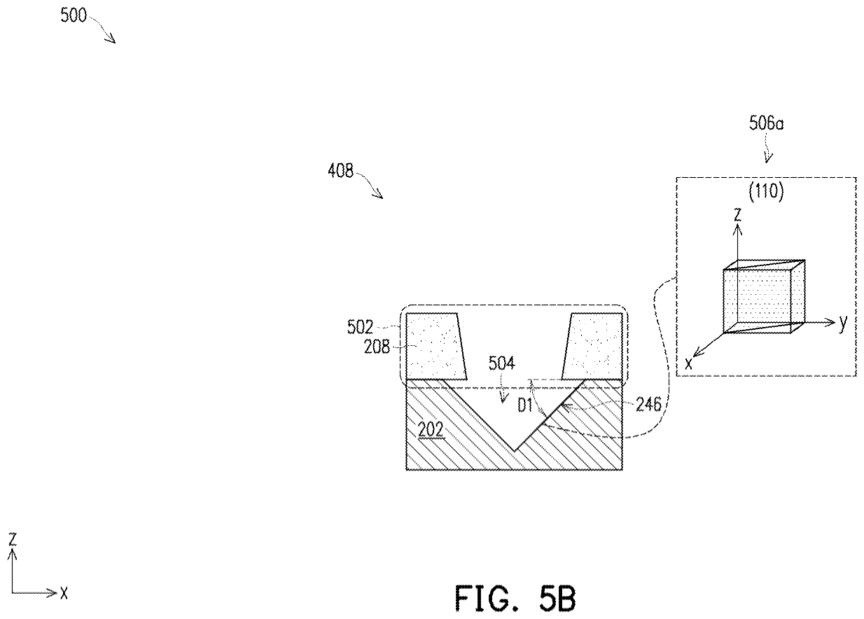

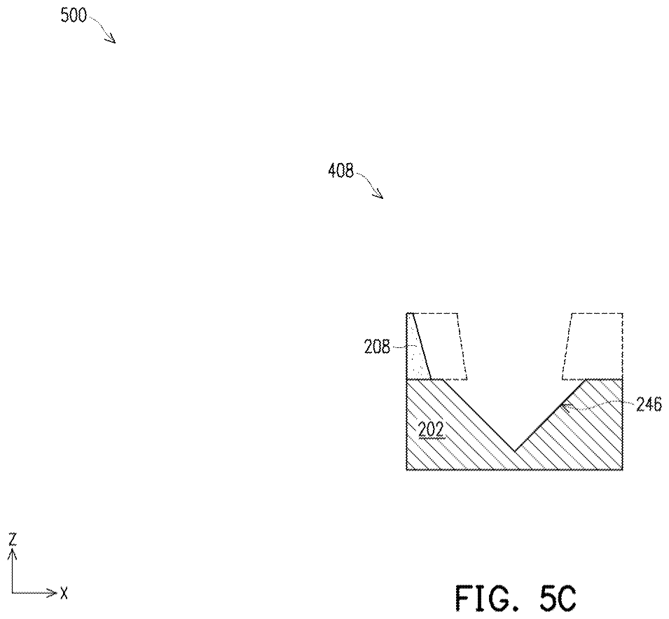

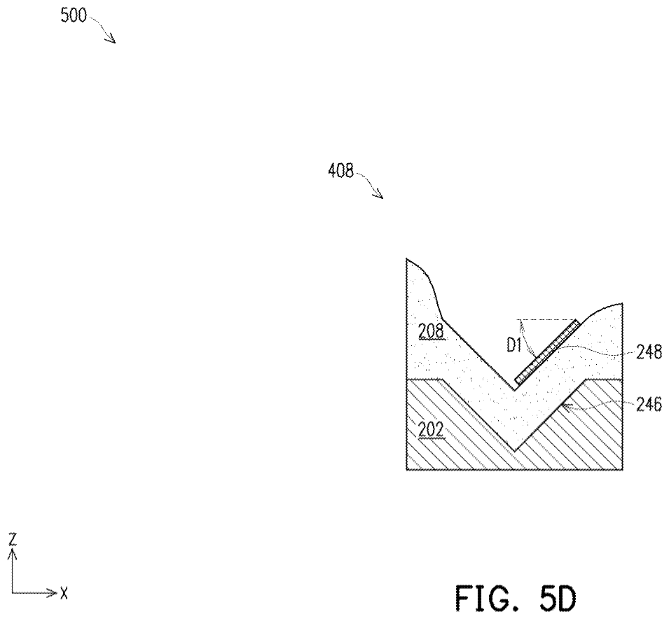

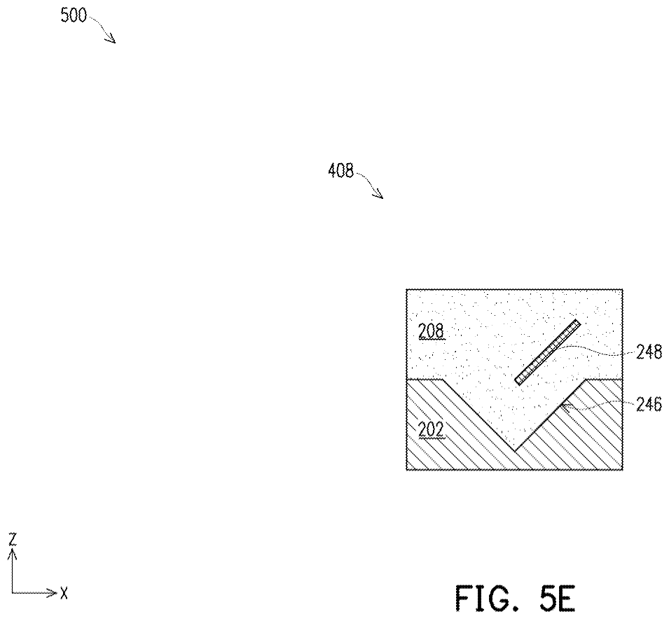

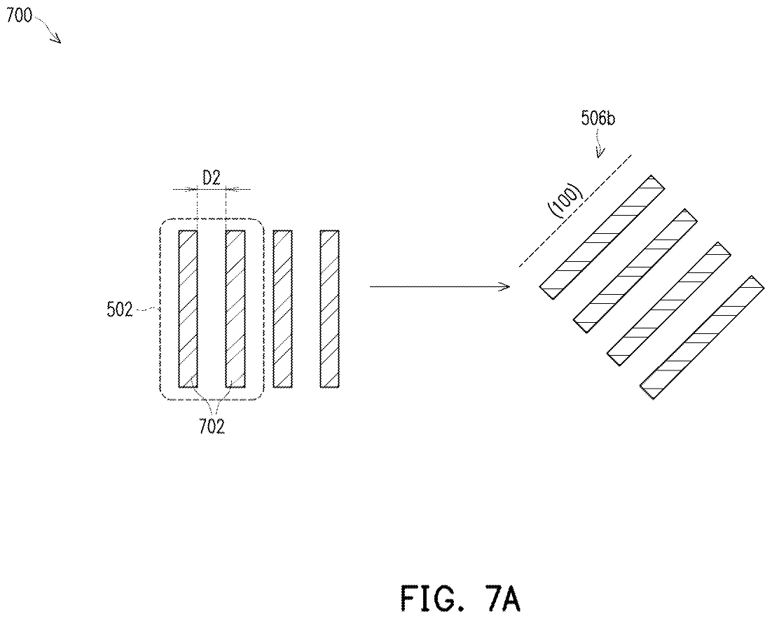

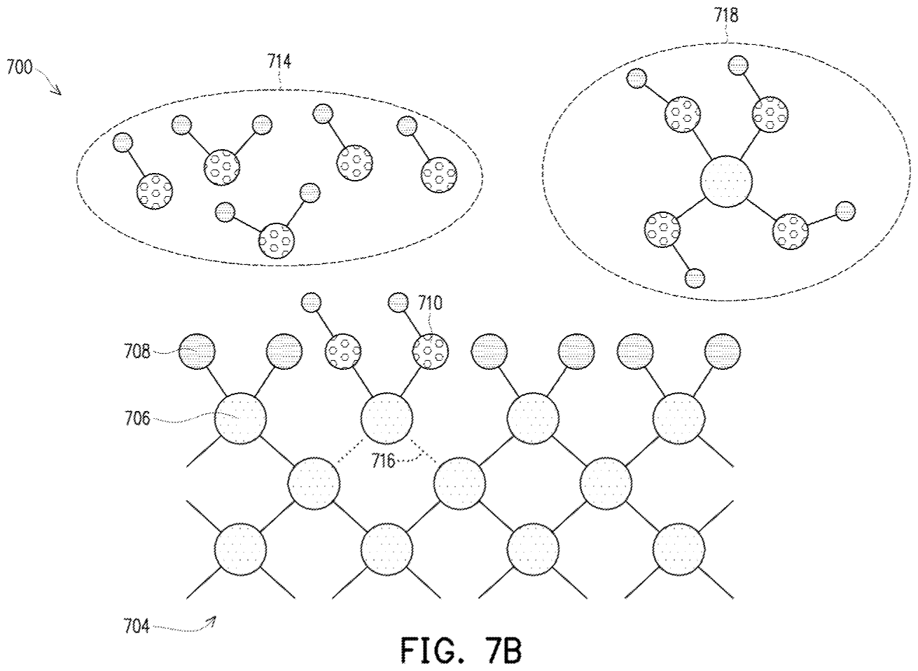

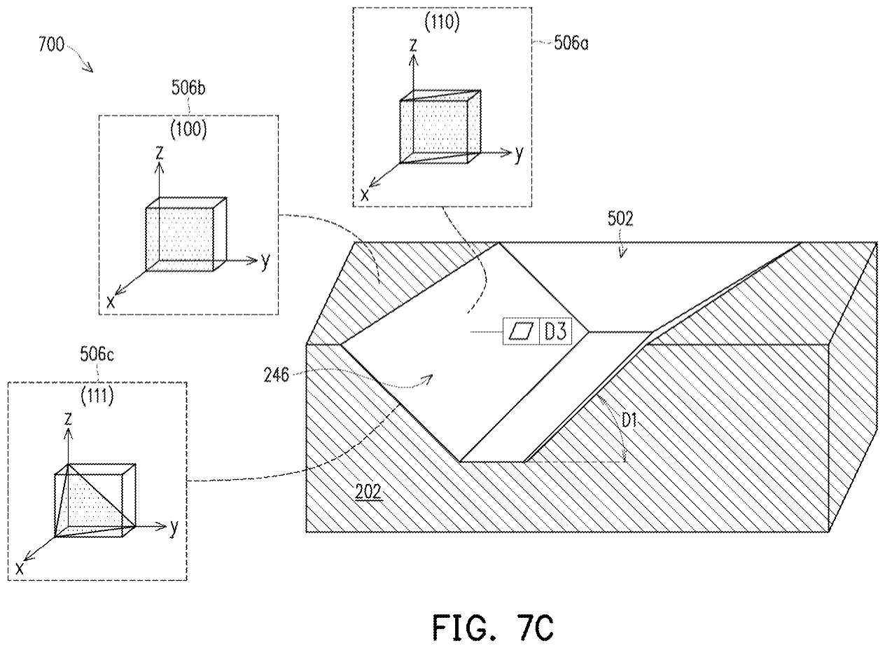

As described in greater detail in connection with FIGS. 5B, 7C, and elsewhere herein, the planar silicon surface 246 is fabricated using a wet chemical etch operation to expose a <110> crystal grain orientation along the planar silicon surface 246. The <110> crystal grain orientation enables a flatness of the planar silicon surface 246 that is increased relative to other planar silicon surfaces formed using other techniques, such as a dry etch operation.

Suspended within the dielectric region 208 over the planar silicon surface 246, the optical signal redirection structure 242 includes a mirror structure 248 that is approximately parallel to the planar silicon surface 246 (e.g., the mirror structure 248 is oriented at the angle D1). The mirror structure 248 is configured to redirect the modulated optical signal 224 from propagation in the x-direction (e.g., a first direction that is approximately parallel with a surface of the silicon substrate 202) in the semiconductor photonics device 200 to the z-direction (e.g., a second direction that is approximately perpendicular to the first direction) in the semiconductor photonics device 200. This enables the mirror structure 248 to direct the modulated optical signal 224 toward an output optical fiber 244 that is coupled with the semiconductor photonics device 200 at the top of the semiconductor photonics device 200 (e.g., as opposed to at a side of the semiconductor photonics device 200).

In some implementations, the angle D1 for the planar silicon surface 246 and the mirror structure 248 is included in a range of approximately 43 degrees to approximately 47 degrees. An angle of at least 43 degrees ensures that within the semiconductor photonics device 200, the mirror structure 248 redirects the modulated optical signal 224 to within a first, outer edge of a receiving zone of the output optical fiber 244 to reduce optical signal loss. An angle of lesser than 43 degrees does not ensure such protection against optical signal loss. Similarly, an angle of less than 47 degrees ensures that within semiconductor photonics device 200, the mirror structure 248 redirects the modulated optical signal 224 to within a second, outer edge of the receiving zone of the output optical fiber 244 to reduce optical signal loss. An angle of greater than 47 degrees does not ensure such protection against optical signal loss. However, other values and ranges for the angle D1 are within the scope of the present disclosure.

The angle D1, in combination with the flatness of the mirror structure 248 that is enabled through the <110> crystal grain orientation, improves positioning of the mirror structure 248 within the optical signal redirection structure 242 relative to another mirror structure within another optical signal redirection structure having an underlying planar silicon surface that is formed using a dry etch technique. In this way, optical signal losses during redirection of the modulated optical signal 224 are decreased to improve a coupling performance between the semiconductor photonics device 200 and the output optical fiber 244.

The mirror structure 248 being configured to direct the modulated optical signal 224 toward the top surface of the semiconductor photonics device 200 (e.g., instead of a side surface of the semiconductor photonics device 200) enables the semiconductor photonics device 200 to be subjected to wafer-level testing prior to the semiconductor photonics device 200 being cut or diced from a semiconductor wafer on which the semiconductor photonics device 200 is manufactured.

Prior to the semiconductor photonics device 200 being cut or diced from the semiconductor wafer, the sides of the semiconductor photonics device 200 are adjoined with other semiconductor dies on the semiconductor wafer. Therefore, outputs from the photonic integrated circuit of the semiconductor photonics device 200 (e.g., which includes the optical modulator 220 and the waveguides 238 and 240) cannot be obtained through the side of the semiconductor photonics device 200 prior to semiconductor photonics device 200 being cut or diced from the semiconductor wafer. The mirror structure 248 being configured to direct the modulated optical signal 224 toward the top surface of the semiconductor photonics device 200 enables the semiconductor photonics device 200 to be subjected to wafer-level testing through the top surface of the semiconductor photonics device 200 prior to the semiconductor photonics device 200 being cut or diced from the semiconductor wafer. For example, the semiconductor photonics device 200 may be subjected to wafer-level testing to verify the operation of the optical modulator 220 and/or the waveguides 238 and 240. Examples include verifying the optical intensity of modulated optical signals 224 generated by the optical modulator 220, verifying the operating frequency of modulated optical signals 224 generated by the optical modulator 220, and/or verifying an error rate of data encoded in modulated optical signals 224 generated by the optical modulator 220, among other examples.

Additionally, and/or alternatively, a propagation distance for modulated optical signals 224 from the dielectric waveguide 240 to the top surface of the semiconductor photonics device 200 may be lesser than the propagation distance for modulated optical signals 224 from the dielectric waveguide 240 to a side surface of the semiconductor photonics device 200. Accordingly, the mirror structure 248 being configured to direct the modulated optical signal 224 toward the top surface of the semiconductor photonics device 200 may reduce optical loss for modulated optical signals 224 in the semiconductor photonics device 200 (which may reduce the operating power consumption of the semiconductor photonics device 200) and/or may enable the semiconductor photonics device 200 to operate at higher data rates, among other examples.

As described in connection with FIG. 2 and elsewhere herein, an optical signal redirection structure (e.g., the optical signal redirection structure 242) includes a planar silicon surface (e.g., the planar silicon surface 246) having a <110> crystal grain orientation. The optical signal redirection structure includes a dielectric region (e.g., the dielectric region 208) over the planar silicon surface. The optical signal redirection structure includes a mirror structure (e.g., the mirror structure 248) suspended in the dielectric region, where the mirror structure is approximately parallel to the planar silicon surface.

Additionally, or alternatively, a semiconductor photonics device (e.g., the semiconductor photonics device 200) includes a silicon substrate (e.g., the silicon substrate 202). The semiconductor photonics device includes a dielectric waveguide (e.g., the dielectric waveguide 240). The semiconductor photonics device includes an optical signal redirection structure (e.g., the optical signal redirection structure 242) including a planar silicon surface (e.g., the planar silicon surface 246) having a particular angle (e.g., the angle D1), a dielectric region (e.g., the dielectric region 208) over the planar silicon surface, and a mirror structure (e.g., the mirror structure 248) suspended in the dielectric region, where the mirror structure is approximately parallel to the planar silicon surface. In some implementations, the particular angle of the planar silicon surface relative to a top, approximately horizontal surface of the silicon substrate, in combination with a flatness of the planar silicon surface, configures the mirror structure to redirect an optical signal (e.g., the modulated optical signal 224) received in a first direction from the dielectric waveguide to a second direction that is approximately perpendicular to the first direction.

As indicated above, FIG. 2 is provided as an example. Other examples may differ from what is described with regard to FIG. 2.

FIGS. 3A and 3B are diagrams of example implementations 300 of a mirror structure described herein (e.g., the mirror structure 248). FIG. 3A illustrates an example implementation 300 in which the mirror structure 248 includes a single-layer structure. In the example implementation 300, the mirror structure 248 may include a highly reflective material, such as aluminum copper (AlCu) and/or tungsten (W), among other examples.

FIG. 3B illustrates an example implementation 302 in which the mirror structure 248 includes a multiple-layer structure. For example, the mirror structure 248 may include a plurality of first layers 304 that are vertically arranged with a plurality of second layers 306 in an alternating manner. In other words, the first layers 304 alternate with the second layers 306 in a direction that is approximately perpendicular to a direction in which the mirror structure 248 extends. In some implementations, one or more properties of the plurality of first layers 304 and/or one or more properties of the plurality of second layers 306 may be selected to optimize the reflectivity of the mirror structure 248 for the modulated optical signal 224. For example, the refractive indices of the first layers 304 and/or the refractive indices of the second layers 306 may be different and may be selected to optimize the reflectivity of the mirror structure 248 for the modulated optical signal 224. In other words, each of the first layers 304 may have a first refractive index, each of the second layers 306 may have a second refractive index, and the first refractive index and the second refractive index may be different refractive indices and may be selected to optimize the reflectivity of the mirror structure 248 for the modulated optical signal 224.

As another example, the thicknesses of the first layers 304 and/or the thicknesses of the second layers 306 may be different and may be selected to optimize the reflectivity of the mirror structure 248 for the modulated optical signal 224. In other words, each of the first layers 304 may have a first thickness (e.g., individual thicknesses for each first layer 304), each of the second layers 306 may have a second thickness (e.g., individual thicknesses for each second layer 306), and the first thickness and the second thickness may be different thicknesses and may be selected to optimize the reflectivity of the mirror structure 248 for the modulated optical signal 224.

As another example, the first layers 304 may each include a first material, and the second layers 306 may each include a second material, where the first material and the second material are selected to optimize the reflectivity of the mirror structure 248 for the modulated optical signal 224. As an example, the first material may include silicon (Si) and the second material may include molybdenum (Mo).

As indicated above, FIGS. 3A and 3B are provided as examples. Other examples may differ from what is described with regard to FIGS. 3A and 3B.

FIGS. 4A-4H are diagrams of an example implementation 400 of forming a portion of a semiconductor photonics device (e.g., a portion of the semiconductor photonics device 200) described herein. In some implementations, one or more of the semiconductor processing operations described in connection with the example implementation 400 may be performed using one or more of the semiconductor processing tools 102-114 and/or by the wafer/die transport tool 116. In some implementations, one or more of the semiconductor processing operations described in connection with the example implementation 400 may be performed using another semiconductor processing tool.

Turning to FIG. 4A, a substrate 402 may be provided. The substrate 402 may include a silicon on insulator (SOI) substrate (or SOI wafer) that includes the silicon substrate 202, a portion of the dielectric region 208 (e.g., a buried oxide or bottom oxide (BOX) layer and/or another type of insulator layer) over and/or on the silicon substrate 202, and a semiconductor layer 404 (e.g., a silicon (Si) layer and/or another type of semiconductor layer) over and/or on the portion of the dielectric region 208.

Alternatively, the silicon substrate 202 may be provided as a semiconductor wafer, and a deposition tool 102 may be used to form the portion of the dielectric region 208 over and/or on the silicon substrate 202, and may form the semiconductor layer 404 over and/or on the portion of the dielectric region 208. A deposition tool 102 may be used to form the portion of the dielectric region 208 using a CVD technique, a PVD technique, an oxidation technique (e.g., a thermal oxidation technique), and/or another type of deposition technique. A deposition tool 102 may be used to form the semiconductor layer 404 using a CVD technique, a PVD technique, an epitaxy technique, and/or another type of deposition technique.

As shown in FIG. 4B, the grating coupler 210, the optical modulator 220, and the semiconductor waveguide 238 may be formed in the semiconductor layer 404. In some implementations, a pattern in a hard mask layer is used to etch the semiconductor layer 404 to form the grating coupler 210, the optical modulator 220, and/or the semiconductor waveguide 238. For example, a deposition tool 102 may be used to form the hard mask layer on the semiconductor layer 404 (e.g., using a CVD technique, a PVD technique, and/or another type of deposition technique), and may be used to form a photoresist layer on the hard mask layer (e.g., using a spin-coating technique and/or another type of deposition technique). An exposure tool 104 may be used to expose the photoresist layer to a radiation source to form a pattern the photoresist layer. A developer tool 106 may be used to develop and remove portions of the photoresist layer to expose the pattern. An etch tool 108 may be used to etch the hard mask layer to transfer the pattern from the photoresist layer to the hard mask layer.

An etch tool 108 may be used to etch the semiconductor layer 404 based on the pattern in the hard mask layer to form the grating coupler 210, the optical modulator 220, and/or the semiconductor waveguide 238 by removing portions of the semiconductor layer 404 based on the pattern. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a photoresist removal tool removes the remaining portions of the photoresist layer (e.g., using a chemical stripper, plasma ashing, and/or another technique). In some implementations, a planarization tool 110 is used to remove the remaining portions of the hard mask layer using a CMP technique and/or another type of planarization technique.

As shown in FIG. 4C, additional material for the dielectric region 208 may be deposited to encapsulate the grating coupler 210, the optical modulator 220, and the semiconductor waveguide 238 in the dielectric region 208. A deposition tool 102 may be used to deposit the additional material for the dielectric region 208 using a CVD technique, a PVD technique, an oxidation technique (e.g., a thermal oxidation technique), and/or another type of deposition technique. In some implementations, a planarization tool 110 is used to planarize the dielectric region 208 after the additional material of the dielectric region 208 is deposited.

As further shown in FIG. 4C, one or more portions of the optical modulator 220 may be doped with one or more types of dopants to form one or more doped regions in the optical modulator 220, including the contacts 226 and 228. For example, an ion implantation tool 114 may be used to implant a portion of the semiconductor material of the optical modulator 220 with p-type ions to form the contact 226. As another example, an ion implantation tool 114 may be used to implant another portion of the semiconductor material of the optical modulator 220 with n-type ions to form the contact 228. The p-type ions and/or the n-type ions may be implanted using an ion implantation technique and/or another type of doping technique.

As further shown in FIG. 4C, the capping layer 230 may be formed over and/or on the top surface of the contacts 226 and 228. A deposition tool 102 may be used to deposit the capping layer 230 using a CVD technique, a PVD technique, an ALD technique, an oxidation technique, and/or another deposition technique. In some implementations, a planarization tool 110 is used to planarize the capping layer 230 such that the top surface of the dielectric region 208 and the top surface of the capping layer 230 are coplanar.

As shown in FIG. 4D, additional material of the dielectric region 208 may be formed over and/or on the grating coupler 210, the optical modulator 220, and/or the semiconductor waveguide 238. A deposition tool 102 may be used to deposit the additional material for the dielectric region 208 using a CVD technique, a PVD technique, an oxidation technique (e.g., a thermal oxidation technique), and/or another type of deposition technique. In some implementations, a planarization tool 110 is used to planarize the dielectric region 208 after the additional material of the dielectric region 208 is deposited.

As further shown in FIG. 4D, the dielectric waveguide 240 may be formed in dielectric region 208 above the semiconductor waveguide 238. The dielectric waveguide 240 may be formed in a recess in the dielectric region 208.

In some implementations, a pattern in a photoresist layer is used to etch the dielectric region 208 to form a recess in the dielectric region 208. In these implementations, a deposition tool 102 may be used to form the photoresist layer on the dielectric region 208. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the dielectric region 208 based on the pattern to form the recess in the dielectric region 208. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric region 208 based on a pattern.

A deposition tool 102 may be used to deposit the dielectric waveguide 240 in the recess in the dielectric region 208 using a CVD technique, a PVD technique, an oxidation technique (e.g., a thermal oxidation technique), and/or another type of deposition technique. In some implementations, a planarization tool 110 is used to planarize the dielectric waveguide 240 after the dielectric waveguide 240 is deposited.

As shown in FIG. 4E, additional material of the dielectric region 208 may be formed over and/or on the grating coupler 210, the optical modulator 220, the semiconductor waveguide 238, and/or the dielectric waveguide 240. A deposition tool 102 may be used to deposit the additional material for the dielectric region 208 using a CVD technique, a PVD technique, an oxidation technique (e.g., a thermal oxidation technique), and/or another type of deposition technique. In some implementations, a planarization tool 110 is used to planarize the dielectric region 208 after the additional material of the dielectric region 208 is deposited.

As further shown in FIG. 4F, the interconnect structures 232 and 234 may be formed in dielectric region 208 over the optical modulator 220. The interconnect structure 232 may be formed over and/or on the contact 226 such that the interconnect structure 232 is electrically coupled and/or physically coupled with the contact 226. The interconnect structure 234 may be formed over and/or on the contact 228 such that the interconnect structure 234 is electrically coupled and/or physically coupled with the contact 228. The interconnect structures 232 and 234 may be formed in recesses in the dielectric region 208.

In some implementations, a pattern in a photoresist layer is used to etch the dielectric region 208 and the capping layer 230 to form the recesses in the dielectric region 208. In these implementations, a deposition tool 102 may be used to form the photoresist layer on the dielectric region 208. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the dielectric region 208 and the capping layer 230 based on the pattern to form the recesses in the dielectric region 208. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric region 208 based on a pattern.

A deposition tool 102 and/or a plating tool 112 may be used to deposit the interconnect structures 232 and 234 in the recesses using a CVD technique, a PVD technique, an ALD technique, an electroplating technique, another deposition technique described above in connection with FIG. 1, and/or another suitable deposition technique. In some implementations, a seed layer is first deposited, and the interconnect structure 232 and/or the interconnect structure 234 is deposited on the seed layer. In some implementations, a planarization tool 110 may be used to planarize the interconnect structure 232 and/or the interconnect structure 234 after the interconnect structure 232 and/or the interconnect structure 234 is deposited.

The interconnect structure 232 may be deposited such that the interconnect structure 232 lands on the contact 226. The interconnect structure 234 may be deposited such that the interconnect structure 234 lands on the contact 228. In some implementations, a silicide layer is formed on the contact 226, and the interconnect structure 232 is formed on the silicide layer. In some implementations, a silicide layer is formed on the contact 228, and the interconnect structure 234 is formed on the silicide layer.

As shown in FIG. 4G, the backend region 206 may be formed over the device region 204. The backend region 206 may be formed in a sequence of operations in which one or more of the dielectric layers 216 are formed, and one or more of the metallization layers 236 are formed in the one or more of the dielectric layers 216. For example, a first dielectric layer of the dielectric layers 216 may be deposited, patterned, and etched. A first metallization layer of the metallization layers 236 may then be deposited in the first dielectric layer. A second dielectric layer of the dielectric layers 216 may be deposited over the first dielectric layer, patterned, and etched. A second metallization layer of the metallization layers 236 may then be deposited in the second dielectric layer. Additional dielectric layers 216 and additional metallization layers 236 may be formed in the backend region 206 in a similar manner.

A deposition tool 102 may be used to deposit the dielectric layers 216 using a PVD technique, an ALD technique, a CVD technique, an oxidation technique, another type of deposition technique described in connection with FIG. 1, and/or another suitable deposition technique. In some implementations, a planarization tool 110 may be used to planarize the dielectric layers 216 after the dielectric layers 216 are deposited.

A deposition tool 102 and/or a plating tool 112 may be used to deposit the metallization layers 236 using a CVD technique, a PVD technique, an ALD technique, an electroplating technique, another deposition technique described above in connection with FIG. 1, and/or another suitable deposition technique. In some implementations, a seed layer is first deposited, and the metallization layers 236 are deposited on the seed layer. In some implementations, a planarization tool 110 may be used to planarize the metallization layers 236 after the metallization layers 236 are deposited.

As shown in FIGS. 4H, a cavity 406 may be formed through the one or more dielectric layers 216 of the backend region 206 and through the dielectric region 208 of the device region 204. The cavity 406 may be formed adjacent to the dielectric waveguide 240. A portion of the silicon substrate 202 may be exposed through the cavity 406. Further, and as described in greater detail in connection with FIGS. 5A-5D and elsewhere herein, the cavity 406 provides access to a region 408 of the semiconductor photonics device 200 for formation of an optical signal redirection structure (e.g., the optical signal redirection structure 242).

In some implementations, a pattern in a photoresist layer is used to etch the passivation layer 218, the one or more dielectric layers 216, the dielectric region 208 to form the cavity 406. In these implementations, a deposition tool 102 may be used to form the photoresist layer on the passivation layer 218. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the passivation layer 218, the one or more dielectric layers 216, the dielectric region 208 based on the pattern to form the cavity 406 through in the passivation layer 218, the one or more dielectric layers 216, the dielectric region 208. In some implementations, the etch operation includes a plasma etch operation, a dry etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the one or more dielectric layers 216 and the dielectric region 208 based on a pattern.

As indicated above, FIGS. 4A-4H are provided as an example. Other examples may differ from what is described with regard to FIGS. 4A-4H.

FIGS. 5A-5E are diagrams of an example implementation 500 of forming an optical signal redirection structure within a semiconductor photonics device (e.g., the optical signal redirection structure 242 within the semiconductor photonics device 200) described herein. In some implementations, one or more of the semiconductor processing operations described in connection with the example implementation 500 may be performed using one or more of the semiconductor processing tools 102-114 and/or by the wafer/die transport tool 116. In some implementations, one or more of the semiconductor processing operations described in connection with the example implementation 500 may be performed using another semiconductor processing tool.

FIG. 5A shows the region 408 including the silicon substrate 202, a portion of the dielectric region 208, and the cavity 406. As described in greater detail in connection with FIGS. 7A-7C, the cavity 406 combined with the portion of the dielectric region 208 may be a hard mask structure 502 that is formed on the silicon substrate 202. In some implementations, a portion of the silicon substrate 202 is removed through the hard mask structure 502 using a wet chemical etch process to form a planar silicon surface (e.g., the planar silicon surface 246) that penetrates into the silicon substrate 202 at an angle relative to a top surface of the silicon substrate 202 (e.g., the planar silicon surface 246).

FIG. 5B shows a cavity 504 formed below the top surface of the silicon substrate 202. As described in greater detail in connection with FIG. 7B, an etch tool 108 may be used to etch the silicon substrate 202 based on a pattern associated with the hard mask structure 502 to form the cavity 504 in the silicon substrate 202. In some implementations, the etch operation is a wet chemical etch operation that uses a tetramethylammonium hydroxide (TMAH) solution or a potassium hydroxide (KOH) solution, among other examples. Furthermore, in some implementations and as shown in FIG. 5B, formation of the cavity 504 includes removing portions of the silicon substrate 202 from under the dielectric region 208 to create overhanging portions of the dielectric region 208.

Within the cavity 504, the planar silicon surface 246 is exposed. Furthermore, a <110> crystal grain orientation 506a on the planar silicon surface 246 is exposed.

FIG. 5C shows removal of portions of the dielectric region 208 (e.g., removal of the hard mask structure 502). In some implementations, a pattern in a photoresist layer is used to etch the dielectric region 208 to remove the portions of the dielectric region 208. In these implementations, a deposition tool 102 may be used to form the photoresist layer on the dielectric region 208. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the dielectric region 208 based on the pattern to remove the portions of the dielectric region 208. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric region 208 based on a pattern.

FIG. 5D shows formation of additional portions of the dielectric region 208, including a portion that is approximately parallel to the planar silicon surface 246. Formation of the additional portions of the dielectric region 208 may include a deposition tool 102 forming a conformal layer of a dielectric material on and/or over the planar silicon surface 246 using a PVD operation, an ALD operation, a CVD operation, an epitaxy operation, an oxidation operation, another type of deposition operation described in connection with FIG. 1, and/or another suitable deposition operation.

As further shown in FIG. 5D, the mirror structure 248 is formed on the additional portions of the dielectric region 208. Forming the mirror structure 248 may include a deposition tool 102 and/or a plating tool 112 using a conformal deposition operation to deposit a mirror layer in a CVD operation, a PVD operation, an ALD operation, an electroplating operation, another deposition operation described above in connection with FIG. 1, and/or another suitable conformal deposition operation. The mirror layer may include a highly reflective material, such as aluminum copper (AlCu) and/or tungsten (W), and/or one or more other combinations of layers of materials as described in connection with FIG. 3B, among other examples.

Forming the mirror structure 248 may further include removing portions of the mirror layer, where remaining portions correspond to the mirror structure 248. In some implementations, a pattern in a photoresist layer is used to etch the mirror layer to form the mirror structure 248. In these implementations, a deposition tool 102 may be used to form the photoresist layer on the mirror layer. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the mirror layer based on the pattern to form the mirror structure 248 from the mirror layer. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the mirror layer based on a pattern.

As shown in FIG. 5D, the mirror structure 248 is approximately parallel to the planar silicon surface 246 (e.g., the mirror structure 248 is positioned at the angle D1). The portion of the dielectric region 208 between the planar silicon surface 246 and the mirror structure 248 may support the mirror structure 248 and/or electrically isolate the mirror structure 248 from the silicon substrate 202.

FIG. 5E shows formation of additional portions of the dielectric region 208 on and/or over the mirror structure 248 to suspend the mirror structure 248 within the dielectric region 208. A deposition tool 102 may be used to deposit the additional portions of the dielectric region 208 (e.g., additional dielectric layers) in a PVD operation, an ALD operation, a CVD operation, an epitaxy operation, an oxidation operation, another type of deposition operation described in connection with FIG. 1, and/or another suitable deposition operation. In some implementations, a planarization tool 110 may be used to planarize the dielectric region 208 after the additional portions are deposited.

Formation of the additional portions of the dielectric region 208 may include a deposition tool 102 depositing additional layers of a dielectric material on and/or over the planar silicon surface 246 using a PVD operation, an ALD operation, a CVD operation, an epitaxy operation, an oxidation operation, another type of deposition operation described in connection with FIG. 1, and/or another suitable deposition operation.

As indicated above, FIGS. 5A-5E are provided as an example. Other examples may differ from what is described with regard to FIGS. 5A-5E.

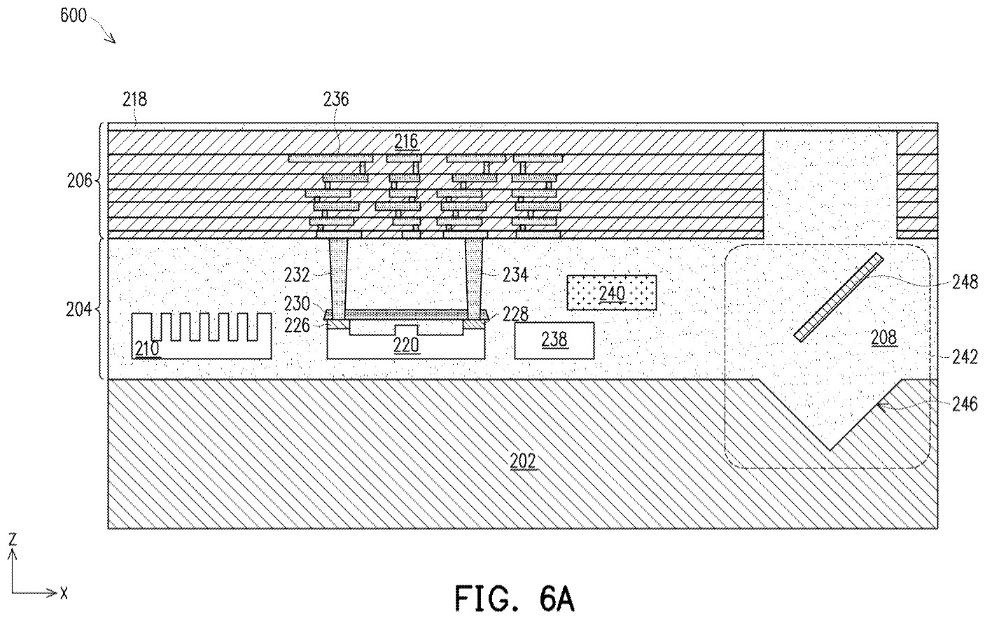

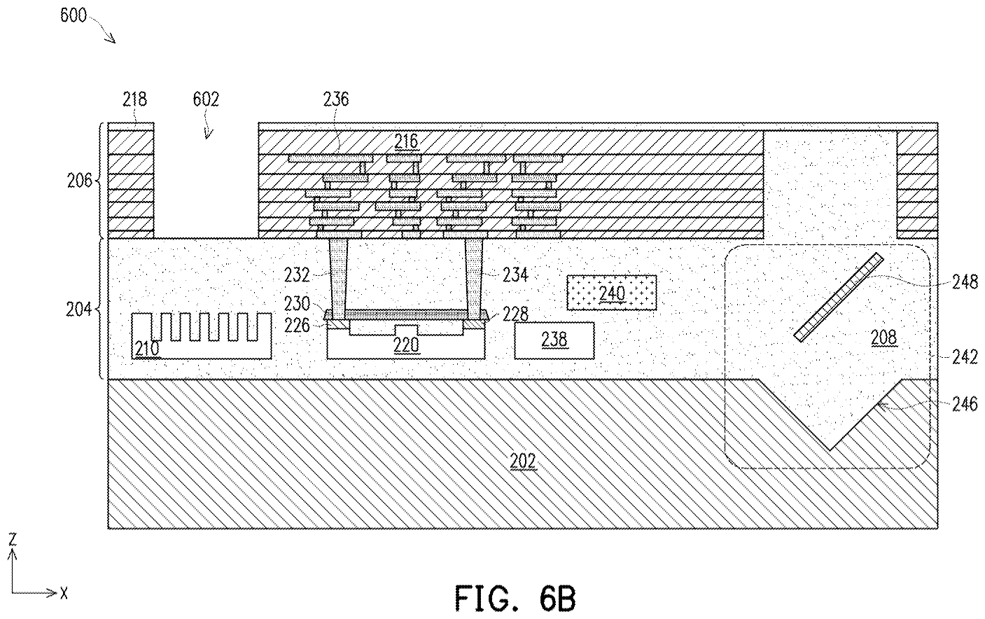

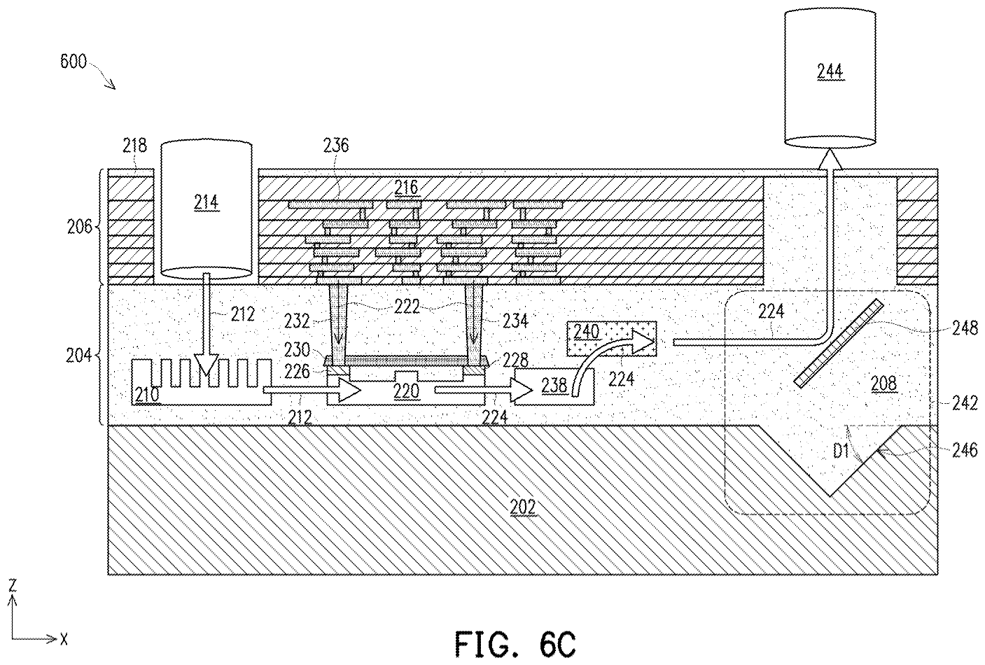

FIGS. 6A-6C are diagrams of an example implementation 600 of forming a portion of a semiconductor photonics device (e.g., a portion of the semiconductor photonics device 200) described herein. In some implementations, one or more of the semiconductor processing operations described in connection with the example implementation 600 may be performed using one or more of the semiconductor processing tools 102-114 and/or by the wafer/die transport tool 116. In some implementations, one or more of the semiconductor processing operations described in connection with the example implementation 600 may be performed using another semiconductor processing tool.

As shown in FIG. 6A, the passivation layer 218 is formed on the dielectric layers 216 and/or the dielectric region 208. A deposition tool 102 may be used to deposit the passivation layer 218 using a PVD technique, an ALD technique, a CVD technique, an oxidation technique, another type of deposition technique described in connection with FIG. 1, and/or another suitable deposition technique. In some implementations, a planarization tool 110 may be used to planarize the passivation layer 218 after the passivation layer 218 is deposited.

As shown in FIG. 6B, a recess 602 is formed in the dielectric layers 216. In some implementations, a pattern in a photoresist layer is used to etch the one or more dielectric layers 216 to form the recess 602. In these implementations, the deposition tool 102 may be used to form the photoresist layer on the passivation layer 218. The exposure tool 104 may be used to expose the photoresist layer to a radiation source to pattern the photoresist layer. The developer tool 106 may be used to develop and remove portions of the photoresist layer to expose the pattern. The etch tool 108 may be used to etch the passivation layer 218 and the one or more dielectric layers 216 based on the pattern to form the recess 602 in the backend region 206. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the passivation layer 218 and the one or more dielectric layers 216 based on a pattern.

As shown in FIG. 6C, the input optical fiber 214 may be inserted into the recess 602 such that the input optical fiber 214 is coupled with the top surface of the semiconductor photonics device 200. The input optical fiber 214 extends into the backend region 206 of the semiconductor photonics device 200 and is located above the grating coupler 210. This enables input optical signals 212 to be provided to the grating coupler 210 from the input optical fiber 214. In some implementations, the input optical fiber 214 is secured in the recess 602 with an adhesive such as an epoxy.

As further shown in FIG. 6C, the output optical fiber 244 may be positioned above the dielectric region 208 such that the output optical fiber 244 is above the mirror structure 248. This enables the modulated optical signals 224 to be redirected from the dielectric waveguide 240 to the output optical fiber 244 by the mirror structure 248. In some implementations, the output optical fiber 244 may be secured above the dielectric region 208 using an epoxy or another suitable fixturing component.

As indicated above, FIGS. 6A-6C are provided as an example. Other examples may differ from what is described with regard to FIGS. 6A-6C.

FIGS. 7A-7C are diagrams of an example implementation 700 of a masking structure described herein. In some implementations, the masking structure corresponds to the hard mask structure 502 described in connection with FIGS. 5A and 5B.

As shown in FIG. 7A, the hard mask structure 502 includes two approximately parallel segments 702 that are separated by distance D2. As an example, and based on a targeted size of and/or volume of a cavity (e.g., the cavity 504 of FIG. 5B), the distance D2 may be approximately 0.8 microns. However, other values for the distance D2 are within the scope of the present disclosure.

As part of a patterning and etching operations to form the hard mask structure 502 as described in connection with FIG. 5A, an inspection system of an exposure tool (e.g., an x-ray diffraction inspection of an exposure tool 104, among other examples) may be used to align a photolithography mask to the <100> crystal grain orientation 506b of the silicon substrate. Further, and as described in greater detail in connection with FIG. 7B, formation of the hard mask structure 502 along the <100> crystal grain orientation 506b, in combination with the wet chemical etch operation of FIG. 5B, may enable etching along a <110> crystal grain orientation (e.g., the <110> crystal grain orientation 506a) to expose a planar silicon surface (e.g., the planar silicon surface 246).

As shown in FIG. 7B, a crystal silicon structure 704 (e.g., a crystal silicon structure of the silicon substrate 202) may include an arrangement of silicon atoms 706, hydrogen atoms 708, and oxygen atoms 710 that are joined through a combination of covalent bonds. In some implementations, and as an example, a solution 714 including tetramethylammonium hydroxide (TMAH) (e.g., a solution including a concentration of approximately 2.38% TMAH at approximately 65 degrees Celsius (° C.)) may provide sufficient energy to break covalent bonds 716 along a <110> crystal grain orientation (e.g., the <110> crystal grain orientation 506a) to remove lattices 718 and expose a planar silicon surface (e.g., the planar silicon surface 246 having the <110> crystal grain orientation 506a). Alternatively, another solution including potassium hydroxide (KOH) may provide sufficient energy to break covalent bonds along the <110> crystal grain orientation to remove the lattices 718.

FIG. 7C shows an isometric view of the cavity 504 in relation to the silicon substrate 202. As shown in FIG. 7C, the planar silicon surface 246 includes a flatness D3. The flatness D3 may be less than approximately 100 microns. A flatness of less than approximately 100 microns ensures that a tolerance stack impacting an angle of a mirror structure (e.g., a tolerance stack impacting the angle D1 of the mirror structure 248) is minimized to reduce an optical signal loss within an optical signal redirection structure (e.g., the optical signal redirection structure 242 redirecting the modulated optical signal 224 received from the dielectric waveguide 240 to the output optical fiber 244). A flatness of not less than approximately 100 microns does not ensure protection against the tolerance stack and/or such an optical signal loss. However, other values and ranges for the flatness D3 are within the scope of the present disclosure.

In addition to the planar silicon surface 246 that includes the crystal grain orientation <110> 506a, and as a result of the wet chemical etch operation, a corner at an edge of the planar silicon surface 246 may include the <111> crystal grain orientation 506c. Additionally, or alternatively, a top surface of the silicon substrate 202 may include the <100> crystal grain orientation 506b.

As indicated above, FIGS. 7A-7C are provided as examples. Other examples may differ from what is described with regard to FIGS. 7A-7C.

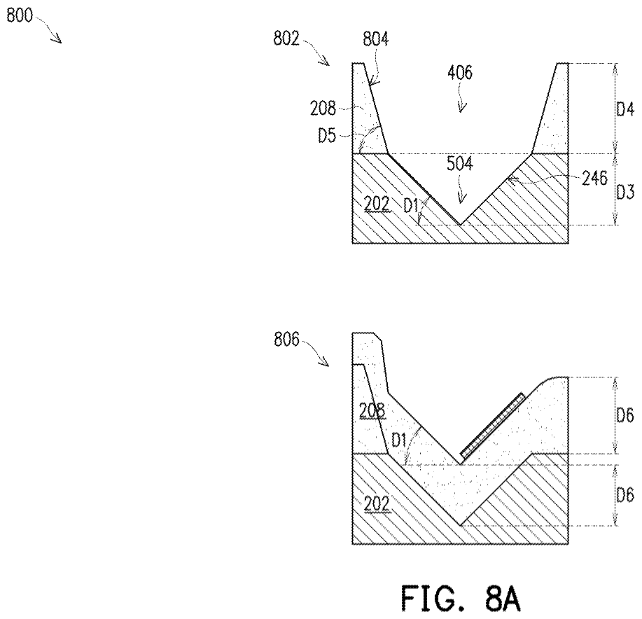

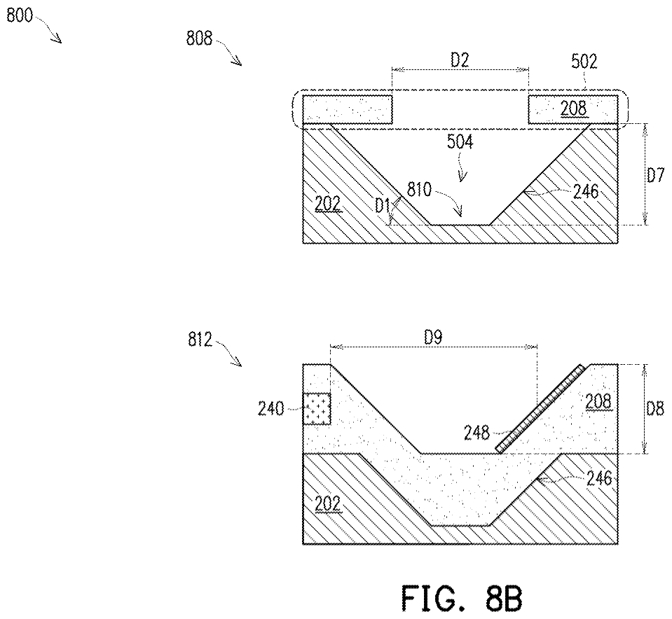

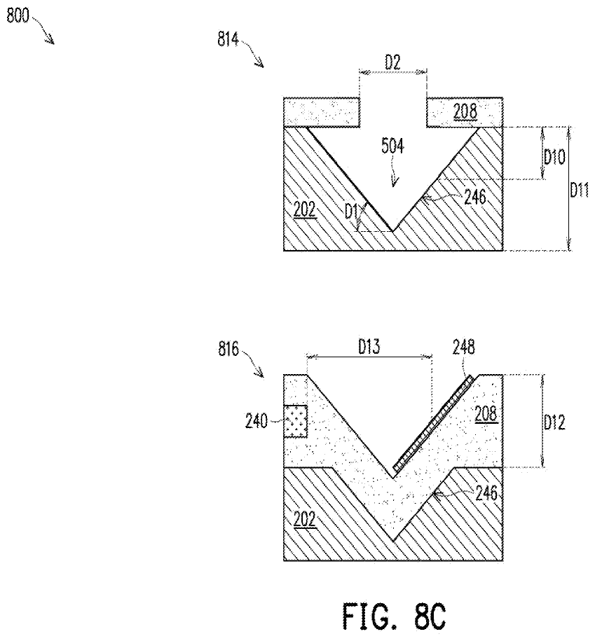

FIGS. 8A-8C are diagrams of example implementations 800 related to formation of an optical signal redirection structure (e.g., the optical signal redirection structure 242) described herein. In some implementations, one or more of the semiconductor processing operations described in connection with the example implementations 800 may be performed using one or more of the semiconductor processing tools 102-114 and/or by the wafer/die transport tool 116. In some implementations, one or more of the semiconductor processing operations described in connection with the example implementations 800 may be performed using another semiconductor processing tool.

As shown in FIG. 8A, and as part of an example operation 802, the cavities 406 and 504 may be formed using a wet chemical etch operation. The cavity 504 may include the planar silicon surface 246 oriented at the angle D1 as described in connection with FIG. 2, FIG. 5B, and elsewhere herein. The cavity 504 may further have a depth D3 of approximately 7 microns. Additionally, or alternatively, the dielectric region 208 (e.g., formed by the cavity 406) may have a thickness D4 of approximately 9 microns and a surface 804 that is oriented at an angle D5 of approximately 85 degrees relative to a top surface of the silicon substrate 202. In combination with the example operation 802 (e.g., an operation including the chemical wet etch operation), and as shown in example operation 806 (e.g., an operation including a conformal deposition operation that deposits a conformal dielectric layer on the dielectric region 208), a thickness D6 related to an increased thickness of the dielectric region 208 (e.g., a thickness at a bottom of the cavity 504 and a thickness above the silicon substrate 202) may be approximately 7 microns.

In some implementations, values and/or ranges for one or more of the dimensions D1, D3, D4, D5, and D6 are related to a processing time (e.g., a processing time associated with the wet chemical etch operation). However, other values and/or ranges for the dimensions D1, D3, D4, D5, and/or D6 are within the scope of the present disclosure.

As shown in FIG. 8B, and as part of an example operation 808, the cavity 504 may be formed using the hard mask structure 502 in combination with a wet chemical etch operation. The hard mask structure 502 may include segments (e.g., segments of the dielectric region 208) that are separated by the distance D2 as described in connection with FIG. 7A (e.g., approximately 8.8 microns). In addition to the planar silicon surface 246 oriented at the angle D1, the cavity 504 may include a bottom surface 810 that is approximately horizontal. The cavity 504 may further include a depth D7 that is approximately 8.8 microns). In combination with the example operation 808 (e.g., an operation including the wet chemical etch operation), and as shown in operation 812 (e.g., an operation including a conformal deposition operation that deposits a conformal dielectric layer on the dielectric region 208), an increased thickness D8 of the dielectric region 208 (e.g., a thickness of the conformal dielectric layer above the silicon substrate 202) may be approximately 8.8 microns. In FIG. 8B, a distance D9 between a tip of the dielectric waveguide 240 and a reflective point of the mirror structure 248 may be approximately 15.4 microns.

In some implementations, values and/or ranges for one or more of the dimensions D1, D2, D7, D8, and/or D9 are related to a processing time (e.g., the wet chemical etch processing time). However, other values and/or ranges for the dimensions D1, D2, D7, D8, and/or D9 are within the scope of the present disclosure.

As shown in FIG. 8C, and as part of an example operation 814, the cavity 504 may be formed using the hard mask structure 502. In contrast to the example operation 808 of FIG. 8B, the example operation 814 may include using a dry etch operation followed by a wet chemical etch operation. In some implementations, an inclusion of the dry etch operation decreases a processing time for formation of the cavity 504 (e.g., decreases a processing time relative to formation of the cavity 504 using the operation 808 of FIG. 8B).

In FIG. 8C, the hard mask structure 502 may include segments (e.g., segments of the dielectric region 208) that are separated by the distance D2 as described in connection with FIG. 7A (e.g., approximately 8.8 microns). During the example operation 808, the dry etch operation may vertically etch the silicon substrate 202 to a depth D10 of approximately 4.4 microns. Subsequent to the dry etch operation, the wet chemical etch operation may etch the cavity 504 to a depth D11 approximately 8.8 microns to form the planar silicon surface 246 oriented at the angle D1. In combination with the example operation 814 (e.g., the operation including dry etch operation and the wet chemical etch operation), and as shown in operation 816 (e.g., an operation including a conformal deposition operation that deposits a conformal dielectric layer on the dielectric region 208), an increased thickness D12 of the dielectric region 208 (e.g., a thickness of the conformal dielectric layer above the silicon substrate 202) may be approximately 8.8 microns. In FIG. 8C, a distance D13 between the tip of the dielectric waveguide 240 and the reflective point of the mirror structure 248 may be approximately 6.6 microns.

In some implementations, values and/or ranges for one or more of the dimensions D1, D2, D10, D11, D12, and/or D13 are related to a processing time (e.g., a processing time associated with the dry etch operation and/or the wet chemical etch operation). However, other values and/or ranges for the dimensions D1, D2, D10, D11, D12, and/or D13 are within the scope of the present disclosure.

As described in connection with FIGS. 8B and 8C, and in some implementations, a distance between the tip of the dielectric waveguide 240 and the reflective point of the mirror structure 248 (e.g., D9 and/or D13) is included in a range of approximately 6.6 microns to approximately 15.4 microns. A distance of at least approximately 6.6 microns ensures that component layout and/or spacing within a semiconductor photonics device (e.g., the dielectric waveguide 240, the mirror structure 248, and/or the output optical fiber 244 within the semiconductor photonics device 200) are mechanically compatible without interference. A lesser distance may not ensure such compatibility. A distance of no more than approximately 15.4 microns may mitigate optical signal losses during redirection of an optical signal (e.g., redirection of the modulated optical signals 224). A distance of greater than 15.4 microns may not mitigate such optical signal losses. However, other values and ranges for the distance between the tip of the dielectric waveguide 240 and the reflective point of the mirror structure 248 are within the scope of the present disclosure.

As indicated above, FIGS. 8A-8C are provided as examples. Other examples may differ from what is described with regard to FIGS. 8A-8C.

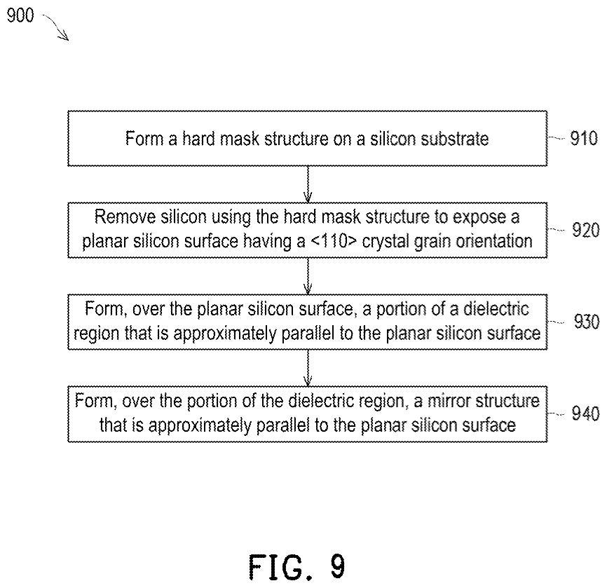

FIG. 9 is a flowchart of an example process 900 associated with forming an optical signal redirection structure described herein (e.g., the optical signal redirection structure 242). In some implementations, one or more process blocks of FIG. 9 are performed using one or more semiconductor processing tools (e.g., one or more of the semiconductor processing tools 102-114).

As shown in FIG. 9, process 900 may include forming a hard mask structure on a silicon substrate (block 910). For example, one or more of the semiconductor processing tools 102-114 may be used to form a hard mask structure (e.g., the hard mask structure 502) on a silicon substrate (e.g., the silicon substrate 202), as described herein.

As further shown in FIG. 9, process 900 may include removing silicon using the hard mask structure to expose a planar silicon surface having a <110> crystal grain orientation (block 920). For example, one or more of the semiconductor processing tools 102-114 may be used to remove silicon using the hard mask structure to expose a planar silicon surface (e.g., the planar silicon surface 246) having a <110> crystal grain orientation, as described herein.

As further shown in FIG. 9, process 900 may include forming, over the planar silicon surface, a portion of a dielectric region that is approximately parallel to the planar silicon surface (block 930). For example, one or more of the semiconductor processing tools 102-114 may be used to form, over the planar silicon surface, a portion of a dielectric region (e.g., the dielectric region 208) that is approximately parallel to the planar silicon surface, as described herein.

As further shown in FIG. 9, process 900 may include forming, over the portion of the dielectric region, a mirror structure that is approximately parallel to the planar silicon surface (block 940). For example, one or more of the semiconductor processing tools 102-114 may be used to form, over the portion of the dielectric region, a mirror structure (e.g., the mirror structure 248) that is approximately parallel to the planar silicon surface, as described herein.

Process 900 may include additional implementations, such as any single implementation or any combination of implementations described below and/or in connection with one or more other processes described elsewhere herein.

In a first implementation, forming the hard mask structure on the silicon substrate includes forming a hard mask layer on the silicon substrate using a deposition operation, and patterning the hard mask layer using a lithography operation in combination with a dry etch operation.

In a second implementation, alone or in combination with the first implementation, patterning the hard mask layer includes aligning a lithography patterning mask to a <100> crystal grain orientation of the silicon substrate.

In a third implementation, alone or in combination with one or more of the first and second implementations, forming the oxide layer on the silicon substrate using the deposition operation includes using the deposition operation to deposit a silicon oxide layer, using the deposition operation to deposit a silicon nitride layer, or using the deposition operation to deposit an aluminum oxide layer.

In a fourth implementation, alone or in combination with one or more of the first through third implementations, removing silicon using the hard mask structure to expose the planar silicon surface includes using the hard mask structure to mask one or more etch operations.

In a fifth implementation, alone or in combination with one or more of the first through fourth implementations, using the hard mask structure to mask one or more etch operations includes using the hard mask structure to mask a wet chemical etch operation that uses a tetramethylammonium hydroxide solution.

In a sixth implementation, alone or in combination with one or more of the first through fifth implementations, using the hard mask structure to mask one or more etch operations includes using the hard mask structure to mask a wet chemical etch operation that uses a potassium hydroxide solution.

In a seventh implementation, alone or in combination with one or more of the first through sixth implementations, using the hard mask structure to mask one or more etch operations includes using the hard mask structure to mask a dry etch operation.

In an eighth implementation, alone or in combination with one or more of the first through seventh implementations, forming the portion of the dielectric region that is approximately parallel to the planar silicon surface includes using a deposition operation to form the portion of the dielectric region, where the portion of the dielectric region is a dielectric layer that conforms along an angle of the planar silicon surface relative to a top, approximately horizontal surface of the silicon substrate.

In a ninth implementation, alone or in combination with one or more of the first through eighth implementations, the portion of the dielectric region is a first portion and further including forming a second portion of the dielectric region over the mirror structure to suspend the mirror structure within the dielectric region at an angle that is approximately parallel to the planar silicon surface.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

In some implementations described herein, a semiconductor photonics device includes a photonic integrated circuit and is coupled with an output optical fiber at a top surface of the semiconductor photonics device. To facilitate coupling of a modulated optical signal to the output optical fiber at the top surface of the semiconductor photonics device, the semiconductor photonics device includes an optical signal redirection structure. The optical signal redirection structure includes a mirror structure that is above and parallel to a planar silicon surface, where the planar silicon surface penetrates into a substrate of the semiconductor photonics device at an angle. The mirror structure redirects the modulated optical signal received from a first direction to a second direction that is toward the output optical fiber. Techniques to fabricate the optical signal redirection structure include forming the planar silicon surface using a wet chemical etch operation. The wet chemical etch operation exposes a <110> crystal grain orientation to improve geometric properties (e.g., the nominal angle and/or the flatness) relative to another planar silicon surface formed using the dry etch operation.

In this way, optical signal losses during redirection of the modulated optical signal from the first direction to the second direction is decreased to and improve a coupling performance between the semiconductor photonics device and the output optical fiber. The improved coupling performance increases an operating efficiency of the semiconductor photonics device, among other examples.

In some implementations described herein, a semiconductor photonics device includes a photonic integrated circuit and is coupled with an output optical fiber at a top surface of the semiconductor photonics device. To facilitate coupling of a modulated optical signal to the output optical fiber at the top surface of the semiconductor photonics device, the semiconductor photonics device includes an optical signal redirection structure. The optical signal redirection structure includes a mirror structure that is above and parallel to a planar silicon surface, where the planar silicon surface penetrates into a substrate of the semiconductor photonics device at an angle. The mirror structure redirects the modulated optical signal received from a first direction to a second direction that is toward the output optical fiber. Techniques to fabricate the optical signal redirection structure include forming the planar silicon surface using a wet chemical etch operation. The wet chemical etch operation exposes a <110> crystal grain orientation to improve geometric properties (e.g., the nominal angle and/or the flatness) relative to another planar silicon surface formed using the dry etch operation.

In this way, optical signal losses during redirection of the modulated optical signal from the first direction to the second direction are decreased to improve a coupling performance between the semiconductor photonics device and the output optical fiber. The improved coupling performance may increase an operating efficiency of the semiconductor photonics device, among other examples.

As described in greater detail above, some implementations described herein provide an optical signal redirection structure. The optical signal redirection structure includes a planar silicon surface having a particular angle. The optical signal redirection structure includes a dielectric region over the planar silicon surface. The optical signal redirection structure includes a mirror structure suspended in the dielectric region, where the mirror structure is approximately parallel to the planar silicon surface.

As described in greater detail above, some implementations described herein provide a semiconductor photonics device. The semiconductor photonics device includes a silicon substrate. The semiconductor photonics device includes a dielectric waveguide. The semiconductor photonics device includes an optical signal redirection structure, including, a planar silicon surface having a particular angle, a dielectric region over the planar silicon surface, and a mirror structure suspended in the dielectric region, where the mirror structure is approximately parallel to the planar silicon surface. In some implementations, the particular angle of the planar silicon surface relative to a top, approximately horizontal surface of the silicon substrate, in combination with a flatness of the planar silicon surface, configures the mirror structure to redirect an optical signal received in a first direction from the dielectric waveguide to a second direction that is approximately perpendicular to the first direction.

As described in greater detail above, some implementations described herein provide a method. The method includes forming a hard mask structure on a silicon substrate. The method includes removing silicon using the hard mask structure to expose a planar silicon surface having a <110> crystal grain orientation. The method includes forming, over the planar silicon surface, a portion of a dielectric region that is approximately parallel to the planar silicon surface. The method includes forming, over the portion of the dielectric region, a mirror structure that is approximately parallel to the planar silicon surface.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An optical signal redirection structure, comprising:
a planar silicon surface having a <110> crystal grain orientation;
a dielectric region over the planar silicon surface; and
a mirror structure suspended in the dielectric region,
wherein the mirror structure is approximately parallel to the planar silicon surface.

2. The optical signal redirection structure of claim 1, wherein a flatness of the planar silicon surface is less than approximately 100 microns.

3. The optical signal redirection structure of claim 1, wherein the planar silicon surface penetrates into a silicon substrate at an angle from a top, approximately horizontal surface of the silicon substrate.

4. The optical signal redirection structure of claim 3, wherein the angle is included in a range from approximately 43 degrees to approximately 47 degrees.

5. The optical signal redirection structure of claim 1, wherein the dielectric region comprises:
an oxide material.

6. The optical signal redirection structure of claim 1, further comprising:
a corner having a <111> crystal grain orientation,
wherein the corner is at an edge of the planar silicon surface.

7. A semiconductor photonics device, comprising:
a silicon substrate;
a dielectric waveguide; and
an optical signal redirection structure, comprising:
a planar silicon surface having a particular angle;
a dielectric region over the planar silicon surface; and
a mirror structure suspended in the dielectric region,
wherein the mirror structure is approximately parallel to the planar silicon surface, and
wherein the particular angle of the planar silicon surface relative to a top, approximately horizontal surface of the silicon substrate, in combination with a flatness of the planar silicon surface, configures the mirror structure to redirect an optical signal received in a first direction from the dielectric waveguide to a second direction that is approximately perpendicular to the first direction.

8. The semiconductor photonics device of claim 7, wherein a distance between a tip of the dielectric waveguide and a reflective point of the mirror structure that redirects the optical signal from the first direction to the second direction is included in a range of approximately 6.6 microns to approximately 15.4 microns.

9. The semiconductor photonics device of claim 8, further comprising:
an output optical fiber over the planar silicon surface.

10. The semiconductor photonics device of claim 9, further comprising:
a passivation layer between the output optical fiber and the planar silicon surface.

11. A method, comprising:
forming a hard mask structure on a silicon substrate;
removing silicon using the hard mask structure to expose a planar silicon surface having a <110> crystal grain orientation;
forming, over the planar silicon surface, a portion of a dielectric region that is approximately parallel to the planar silicon surface; and
forming, over the portion of the dielectric region, a mirror structure that is approximately parallel to the planar silicon surface.

12. The method of claim 11, wherein forming the hard mask structure on the silicon substrate includes:
forming a hard mask layer on the silicon substrate using a deposition operation; and
patterning the hard mask layer using a lithography operation in combination with a dry etch operation.

13. The method of claim 12, wherein patterning the hard mask layer includes:
aligning a lithography patterning mask to a <100> crystal grain orientation of the silicon substrate.

14. The method of claim 12, wherein forming the hard mask layer on the silicon substrate using the deposition operation includes:
using the deposition operation to deposit a silicon oxide layer,
using the deposition operation to deposit a silicon nitride layer, or
using the deposition operation to deposit an aluminum oxide layer.

15. The method of claim 11, wherein removing silicon using the hard mask structure to expose the planar silicon surface includes:
using the hard mask structure to mask one or more etch operations.

16. The method of claim 15, wherein using the hard mask structure to mask one or more etch operations includes:
using the hard mask structure to mask a wet chemical etch operation that uses a tetramethylammonium hydroxide solution.

17. The method of claim 15, wherein using the hard mask structure to mask one or more etch operations includes:
using the hard mask structure to mask a wet chemical etch operation that uses a potassium hydroxide solution.

18. The method of claim 15, wherein using the hard mask structure to mask one or more etch operations includes:
using the hard mask structure to mask a dry etch operation.

19. The method of claim 11, wherein forming the portion of the dielectric region (208) that is approximately parallel to the planar silicon surface includes:
using a deposition operation to form the portion of the dielectric region,
wherein the portion of the dielectric region is a dielectric layer that conforms along an angle of the planar silicon surface relative to a top, approximately horizontal surface of the silicon substrate.

20. The method of claim 11, wherein the portion of the dielectric region is a first portion and further including:
forming a second portion of the dielectric region over the mirror structure to suspend the mirror structure within the dielectric region at an angle that is approximately parallel to the planar silicon surface.
